(19) United States
(12) Patent Application Publication
(10) Pub. No.: US 2026/0143888 A1
(43) Pub. Date: May 21, 2026

(54) DISPLAY DEVICE

(71) Applicant: LG Display Co., Ltd., Seoul (KR)

(72) Inventor: NamYong GONG, Paju-si (KR)

(73) Assignee: LG Display Co., Ltd., Seoul (KR)

(21) Appl. No.: 19/246,411

(22) Filed: Jun. 23, 2025

(30) Foreign Application Priority Data
Nov. 21, 2024 (KR) 10-2024-0167594

(51) Int. Cl. H10H 29/85; G06F 3/041; G06F 3/044; H10H 29/49

(52) U.S. Cl. CPC H10H 29/8508; G06F 3/0412; G06F 3/0416; G06F 3/0446; H10H 29/49; G06F 2203/04102

(57) ABSTRACT

A new foldable display device can include a substrate capable of being bent, a plurality of drivers disposed on the substrate, a plurality of light emitting devices disposed on the plurality of drivers, a plurality of column lines, and a plurality of row lines. The substrate includes a first display area, a second display area, a third display area, a first bending area between the first display area and the second display area, and a second bending area between the second display area and the third display area.

### CROSS-REFERENCE TO RELATED APPLICATION

This application claims priority to Korean Patent Application No. 10-2024-0167594, filed in the Republic of Korea on Nov. 21, 2024, which is hereby expressly incorporated by reference for all purposes as if fully set forth herein into the present application.

### BACKGROUND

### Field

Embodiments of the present disclosure relate to an apparatus and particularly to, for example, without limitation, a display device.

### Discussion of the Related Art

As the information society develops, the demand for display devices for displaying images is increasing in various forms, and recently, various display devices such as a liquid crystal display device and an organic light-emitting display device are being utilized.

A display device can be a flexible display device capable of bending or folding.

### SUMMARY OF THE DISCLOSURE

Embodiments of the present disclosure can provide a foldable display device having a plurality of display areas.

Embodiments of the present disclosure can provide a display device capable of being foldable and detecting a touch by including a plurality of display areas.

Embodiments of the present disclosure can provide a display device with a new foldable structure capable of enabling the low power consumption.

Embodiments of the present disclosure can provide a display device including a substrate including a plurality of display areas, and being able to be bent between the plurality of display areas, a plurality of drivers disposed on the substrate and disposed in the plurality of display areas, a plurality of light emitting devices disposed on the plurality of drivers and overlapping with the plurality of drivers, a plurality of column lines electrically connected to a first electrode of each of the plurality of light emitting devices, and a plurality of row lines electrically connected to a second electrode of each of the plurality of light emitting devices. The substrate can include a first display area, a second display area spaced apart from the first display area, a third display area spaced apart from the second display area, a first bending area between the first display area and the second display area, and a second bending area between the second display area and the third display area.

Embodiments of the present disclosure can provide a display device including a substrate including a plurality of display areas, and being able to be bent between the plurality of display areas, a plurality of light emitting devices disposed on a plurality of drivers disposed on the substrate, a plurality of column lines electrically connected to a first electrode of each of the plurality of light emitting devices, and a plurality of row lines electrically connected to a second electrode of each of the plurality of light emitting devices, wherein a touch driving signal is supplied to at least some of the plurality of row lines during a touch sensing period. The substrate can include a first display area, a second display area spaced apart from the first display area, a third display area spaced apart from the second display area, a first bending area between the first display area and the second display area, and a second bending area between the second display area and the third display area.

According to embodiments of the present disclosure, it is possible to provide a foldable display device having a plurality of display areas.

According to embodiments of the present disclosure, it is possible to provide a display device capable of being foldable and detecting a touch by including a plurality of display areas.

According to embodiments of the present disclosure, it is possible to provide a display device with a new foldable structure capable of enabling the low power consumption.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The contents of the present disclosure will be more fully understood from the detailed description and the attached drawings provided below, and the detailed description and the attached drawings are provided only for the purpose of explanation and do not limit the scopes of the present disclosure.

FIG. 1 illustrates a display device according to embodiments of the present disclosure.

FIG. 2 is a plan view of a display device according to embodiments of the present disclosure.

FIG. 3 is a plan view of a display panel according to embodiments of the present disclosure.

FIG. 4 illustrates a sub-pixel of a display panel according to embodiments of the present disclosure.

FIG. 5 is a plan view of a display panel according to embodiments of the present disclosure.

FIG. 6 illustrates a unit driving area of a display panel according to embodiments of the present disclosure.

FIG. 7 and FIG. 8 are plan views of a portion of a display panel according to embodiments of the present disclosure.

FIG. 9 is a cross-sectional view of a display panel according to embodiments of the present disclosure.

FIG. 10 is a detailed cross-sectional view of a display panel according to embodiments of the present disclosure, taken along the A-B cutting line of FIG. 5.

FIG. 11 is an enlarged cross-sectional view of a first sub-pixel of a display panel according to embodiments of the present disclosure.

FIG. 12 briefly illustrates a touch sensing structure of a display device according to embodiments of the present disclosure.

FIGS. 13 and 14 illustrate a touch sensor structure of a display panel according to embodiments of the present disclosure.

FIGS. 15 and 16 are driving timing diagrams of a display device according to embodiments of the present disclosure.

FIG. 17 is a cross-sectional view of a foldable display device according to embodiments of the present disclosure.

FIG. 18 illustrates touch electrodes positioned in a touch area according to embodiments of the present disclosure.

FIG. 19 illustrates a process for transmitting integrated sensing data according to embodiments of the present disclosure.

FIG. 20 and FIG. 21 illustrate touch electrodes according to embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted or can be briefly discussed when it is determined that the description can make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments can be provided so that this disclosure can be sufficiently thorough and complete to assist those skilled in the art to fully understand the scope of the present disclosure. Further, the present disclosure is only defined by scopes of claims.

A shape, a size, a ratio, an angle, and a number disclosed in the drawings for describing embodiments of the present disclosure can be merely an example. Thus, the present disclosure is not limited to the illustrated details. Like reference numerals refer to like elements throughout.

Any implementation described herein as an “example” is not necessarily to be construed as preferred or advantageous over other implementations.

In the description of the various embodiments of the present disclosure, where positional relationships are described, for example, when a position relation between two parts is described as, for example, “on,” “over,” “under,” and “next,” or the like, one or more other parts can be located between the two parts unless a more limiting term, such as “just” or “direct(ly)” is used. For example, where an element or layer is disposed “on” another element or layer, a third layer or element can be interposed therebetween.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments can be provided so that this disclosure can be sufficiently thorough and complete to assist those skilled in the art to fully understand the scope of the present disclosure. Furthermore, the present disclosure is only defined by scopes of claims.

Features of various embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship.

Hereinafter, various embodiments of the disclosure are described in detail with reference to the accompanying drawings. All the components of each display device according to all embodiments of the present disclosure are operatively coupled and configured.

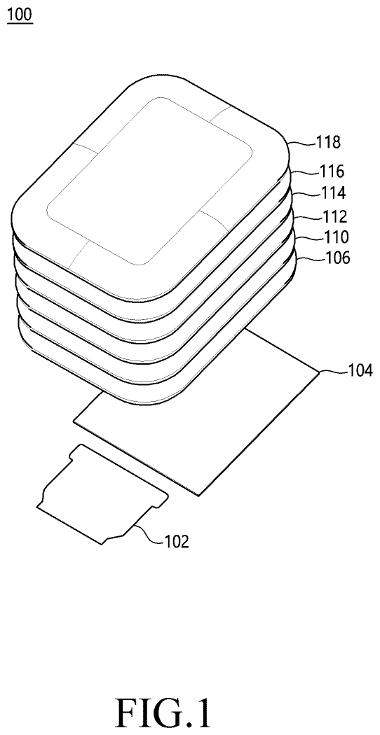

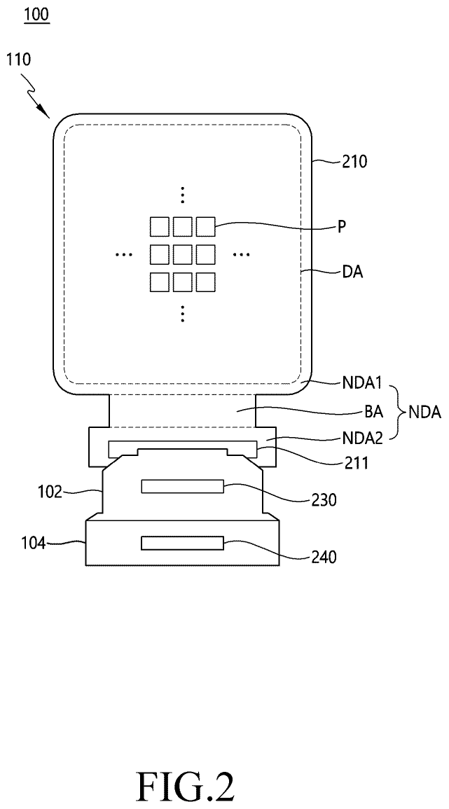

FIG. 1 illustrates a display device 100 according to embodiments of the present disclosure, and FIG. 2 is a plan view of the display device 100 according to embodiments of the present disclosure.

Referring to FIG. 1, the display device 100 according to the embodiments of the present disclosure can include a display panel 110, a cover member 118 disposed on the display panel 110, a flexible printed circuit 102 connected to the display panel 110, and a printed circuit board 104 connected to the flexible printed circuit 102.

The display device 100 according to the embodiments of the present disclosure can further include a support substrate 106 disposed under the display panel 110 and supporting the lower portion of the display panel 110, a polarizing layer 114 disposed on the display panel 110, a first adhesive layer 112 disposed between the display panel 110 and the polarizing layer 114, and a second adhesive layer 116 disposed between the polarizing layer 114 and the cover member 118.

The display panel 110 can include a substrate 210. The substrate 210 can be a member on which various components such as a plurality of metal layers and a plurality of insulating material layers are formed. The substrate 210 can be made of an insulating material. For example, the substrate 210 can be made of glass or resin. In addition, the substrate 210 can be made of a flexible material. For example, the substrate 210 can be made of a flexible plastic material such as polyimide (PI). However, the embodiments of the present disclosure are not limited thereto.

The display panel 110 can display information, images, and/or images provided to a user. For example, the display panel 110 can include a display area DA and a non-display area NDA. For example, the substrate 210 can include a display area DA and a non-display area NDA. The display area DA and the non-display area NDA are not limited to the substrate 210, but can be described throughout the entire display device 100.

The display area DA can be an area where an image is displayed. The display area DA can include a plurality of pixels P. Each of the plurality of pixels P can be composed of a plurality of sub-pixels. At least one light emitting device can be arranged in each of the plurality of sub-pixels. The light emitting device can be configured differently depending on the type of the display device 100. For example, if the display device 100 is an inorganic light emitting display device, the light emitting device can be an inorganic-based light emitting device, such as a light emitting diode (LED), a micro LED, or a mini LED, but the embodiments of the present disclosure are not limited thereto.

The non-display area NDA can be an area where an image is not displayed. In the non-display area NDA, various wirings, and circuits for driving a plurality of pixels P of the display area DA can be arranged. For example, various driving circuits and various wirings can be arranged in the non-display area NDA, and a pad section 211 to which an integrated circuit and a printed circuit are connected can be arranged, but the embodiments of the present disclosure are not limited thereto.

According to the present embodiments, the non-display area NDA can include a first non-display area NDA1, a bending area BA, and a second non-display area NDA2.

The display area DA of the substrate 210 or the display device 100 can be configured in various shapes according to the design of the display device 100.

According to the embodiments of the present disclosure, a width of the second non-display area NDA2 where the pad section 211 is arranged can be wider than a width of the bending area BA. In addition, a width of the display area DA can be wider than the width of the bending area BA. In the drawing, the width of the bending area BA is depicted as being narrower than the width of other areas of the substrate 210, but the shape of the substrate 210 including the bending area BA is an example, and the embodiments of the present disclosure are not limited thereto.

Referring to FIG. 1 and FIG. 2, a flexible printed circuit 102 and a printed circuit board 104 can be disposed at a lower portion of the display panel 110. The flexible printed circuit 102 and the printed circuit board 104 can be arranged at one edge of the display panel 110, but the embodiments of the present disclosure are not limited thereto. One side of the flexible printed circuit 102 can be connected to the display panel 110, and the other side can be connected to the printed circuit board 104, but the embodiments of the present disclosure are not limited thereto. The flexible printed circuit 102 can be a flexible film, but the embodiments of the present disclosure are not limited thereto.

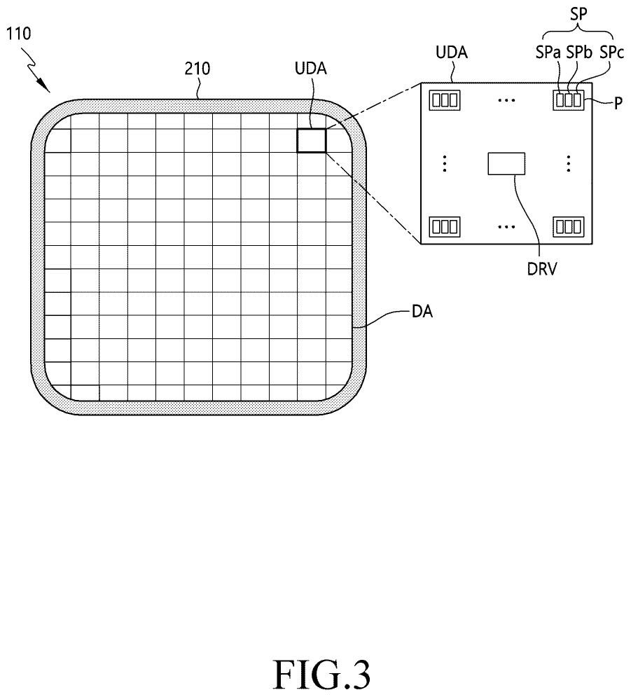

The pad section 211 disposed in the second non-display area NDA2 includes a plurality of pads, and a driving component including one or more flexible printed circuits 102 and a printed circuit board 104 can be attached or bonded. The plurality of pads included in the pad section 211 are electrically connected to one or more flexible printed circuits 102, and can transmit various signals (or power) from the printed circuit board 104 and one or more flexible printed circuits 102 to a driving circuit (for example, a driver DRV of FIG. 3) arranged in the display area DA.

The flexible printed circuit 102 can be a film in which various components are arranged on a flexible base film. For example, a first circuit component 230, such as a gate drive integrated circuit and/or a data drive integrated circuit, can be arranged on one or more flexible printed circuits 102, but the embodiments of the present disclosure are not limited thereto. The first circuit component 230 can be a component that processes data and a driving signal for displaying an image.

The printed circuit board 104 can be a component that is electrically connected to the flexible printed circuit 102 and supplies a signal to the first circuit component 230. The printed circuit board 104 can be arranged on one side of the flexible printed circuit 102 and can be electrically connected to the flexible printed circuit 102. Various components for supplying various signals to the first circuit component 230 can be arranged on the printed circuit board 104.

The printed circuit board 104 can include at least one hole, but the embodiments of the present disclosure are not limited thereto. An internal component detecting ambient light or temperature, such as a plurality of sensors, can be arranged in an area corresponding to at least one hole.

Referring to FIG. 1, a polarizing layer 114 can be arranged on a display panel 110 and can prevent or reduce light generated from an external light source from entering the display panel 110 and affecting a light emitting device.

A cover member 118 can be arranged on a polarizing layer 114 and can be a member for protecting the display panel 110.

A second adhesive layer 116 can be disposed between the polarizing layer 114 and the cover member 118. The second adhesive layer 116 can attach the cover member 118 to the display panel 110 or the polarizing layer 114.

A first adhesive layer 112 can be disposed between the display panel 110 and the polarizing layer 114. The first adhesive layer 112 can attach the polarizing layer 114 to the display panel 110. The first adhesive layer 112 can be omitted.

Each of the first adhesive layer 112 and the second adhesive layer 116 can include an optically clear adhesive (OCA), an optically clear resin (OCR), or a pressure sensitive adhesive (PSA), but the embodiments of the present disclosure are not limited thereto.

The support substrate 106 is disposed between the display panel 110 and the printed circuit board 104 to reinforce the rigidity of the display panel 110. The support substrate 106 can be a back plate, but the embodiments of the present disclosure are not limited thereto.

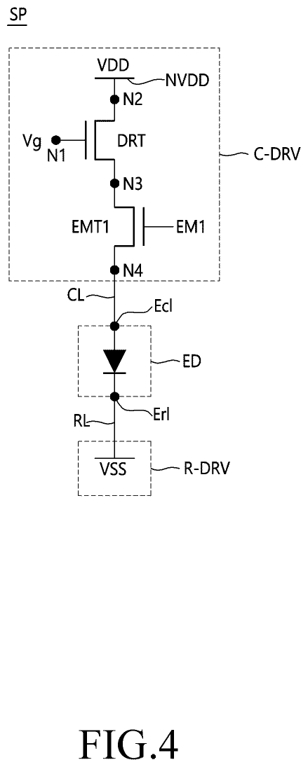

FIG. 3 is a plan view of a display panel 110 according to embodiments of the present disclosure, and FIG. 4 is a plan view of a unit driving area UDA of a display panel 110 according to embodiments of the present disclosure.

Referring to FIG. 3, the display area DA of the display panel 110 according to the embodiments of the present disclosure can include a plurality of unit driving areas UDA.

The display panel 110 according to the embodiments of the present disclosure can include a driver DRV arranged in each of the plurality of unit driving areas UDA.

Each of the plurality of unit driving areas UDA can be a driving area driven by one driver DRV. For example, the plurality of unit driving areas UDA can be independent driving areas driven by different drivers DRV.

The display panel 110 according to the embodiments of the present disclosure can include a substrate 210 including a display area DA, and a plurality of pixels P arranged in a matrix form in the display area DA.

A plurality of pixels P can be arranged in each of the plurality of unit driving areas UDA. Each of the plurality of pixels P can include a plurality of sub-pixels SP. Each of the plurality of sub-pixels SP can include at least one light emitting device.

FIG. 4 illustrates a sub-pixel SP of a display panel 110 according to embodiments of the present disclosure.

Referring to FIG. 4, the sub-pixel SP according to embodiments of the present disclosure can include a light emitting device ED including a first electrode Ecl and a second electrode Erl, a column driver C-DRV for driving a column line CL electrically connected to the first electrode Ecl of the light emitting device ED, and a row driver R-DRV for driving a row line RL electrically connected to the second electrode Erl of the light emitting device ED.

The light emitting device ED can include a first electrode Ecl and a second electrode Erl. The first electrode Ecl can be electrically connected to a column line CL, and the second electrode Erl can be electrically connected to a row line RL. For example, the first electrode Ecl can be an anode electrode, and the second electrode Erl can be a cathode electrode. For another example, the first electrode Ecl can be a cathode electrode, and the second electrode Erl can be an anode electrode.

A column driver C-DRV included in a unit driving area UDA can be connected to a plurality of column lines CL included in the unit driving area UDA, and can drive a plurality of column lines CL included in the unit driving area UDA. Each of the plurality of column lines CL can be commonly connected to the first electrode Ecl of each (e.g., corresponding one) of the plurality of light emitting devices ED included in the plurality of sub-pixels SP arranged in the corresponding column.

A row driver R-DRV included in a unit driving area UDA can be connected to a plurality of row lines RL included in the unit driving area UDA and can drive a plurality of row lines RL included in the unit driving area UDA. Each of the plurality of row lines RL can be commonly connected to a second electrode Erl of each of a plurality of light emitting devices ED included in a plurality of sub-pixels SP arranged in the corresponding row.

The column driver C-DRV can include main nodes including a first node N1, a second node N2, a third node N3, and a fourth node N4. The column driver C-DRV can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the light emitting device ED are electrically connected, and can be a node to which the column line CL is electrically connected. Here, a source electrode or a drain electrode of the first emission control transistor EMT1 and the first electrode Ecl of the light emitting device ED can be commonly connected to the column line CL.

The driving transistor DRT supplies a driving current to make the light emitting device ED emit light, is connected between the second node N2 and the third node N3, and can control the connection between the second node N2 and the third node N3 according to the voltage of the first node N1.

The gate electrode of the driving transistor DRT is electrically connected to the first node N1, and a gate voltage Vg can be applied thereto. The drain electrode or the source electrode of the driving transistor DRT can be electrically connected to the second node N2. The source electrode or the drain electrode of the driving transistor DRT can be electrically connected to the third node N3.

The first emission control transistor EMT1 can control a connection of a path through which the driving current flows, and can play a role in controlling an emission of the light emitting device ED.

If the driving transistor DRT and the first emission control transistor EMT1 are turned on between a high potential voltage VDD and a low-potential voltage VSS, the driving current can be supplied to the light emitting device ED through the driving transistor DRT and the first emission control transistor EMT1. Accordingly, the light emitting device ED can emit light.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The first emission control signal EM1 can be generated by the driver DRV, or can be supplied to the driver DRV from a driving-related circuit such as a timing controller. For example, if the first emission control signal EM1 is a pulse width modulation signal, the first emission control signalEM1) can have a pulse width corresponding to an image signal (e.g., data voltage, data signal). For example, if the pulse width of the first emission control signal EM1 is large, the emission luminance of the light emitting device ED can be high. If the pulse width of the first emission control signal EM1 is small, the emission luminance of the light emitting device ED can be low.

The row driver R-DRV can drive at least one row line RL by supplying a low-potential voltage VSS to at least one row line RL.

The row driver R-DRV can perform display-on driving or display-off driving for one row line RL. The row driver R-DRV can supply a low-potential voltage for display-on driving to one row line RL in order to perform display-on driving for one row line RL. The row driver R-DRV can supply a low-potential voltage for display-off driving to one row line RL in order to perform display-off driving for one row line RL.

A low-potential voltage for display-on driving and a low-potential voltage for display-off driving can be different. For example, the low-potential voltage for display-on driving can be lower than the low-potential voltage for display-off driving. In the embodiments of the present disclosure, the “low-potential voltage for display-on driving” is also referred to as the “first low-potential voltage,” and the “low-potential voltage for display-off driving” is also referred to as the “second low-potential voltage.”

The column driver C-DRV can further include at least one switching element and/or at least one transistor in addition to the driving transistor DRT and the first emission control transistor EMT1. Each of the transistors included in the column driver C-DRV can be an n-type transistor or a p-type transistor.

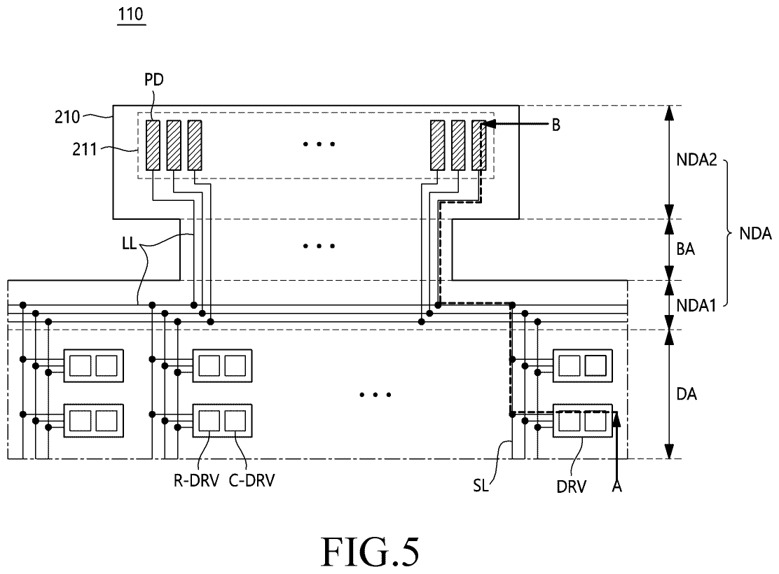

FIG. 5 is a plan view of the display panel 110 according to the embodiments of the present disclosure.

Referring to FIG. 5, the substrate 210 of the display panel 110 according to the embodiments of the present disclosure can include a display area DA and a non-display area NDA, and the non-display area NDA can include a first non-display area NDA1, a bending area BA, and a second non-display area NDA2.

A plurality of drivers DRV can be arranged in the display area DA. Each of the plurality of drivers DRV can be a circuit for driving light emitting devices of a plurality of sub-pixels included in a corresponding unit driving area (UDA of FIG. 4). Each of the plurality of drivers DRV can include a row driver R-DRV for driving a plurality of row lines and a column driver C-DRV for driving a plurality of column lines, in order to drive a plurality of light emitting devices ED included in a corresponding unit driving area (UDA of FIG. 4).

A pad section 211 including a plurality of pads PD can be arranged in the second non-display area NDA2.

A plurality of signal lines SL and a plurality of link lines LL for signal transmission between a plurality of drivers DRV arranged in the display area DA and the pad section 211 can be arranged on the substrate 210. The plurality of signal lines SL can be electrically connected between the plurality of link lines LL and the plurality of drivers DRV. The plurality of link lines LL can electrically connect the plurality of pads PD and the plurality of signal lines SL.

The plurality of link lines LL can be arranged in the non-display area NDA, and all or part of each of the plurality of signal lines SL can be arranged in the display area DA.

Each of the plurality of drivers DRV can receive various signals to perform a driving operation through the plurality of link lines LL and the plurality of signal lines SL. Here, the various signals can include various power voltages and various signals required for the driving operation of each of the plurality of drivers DRV.

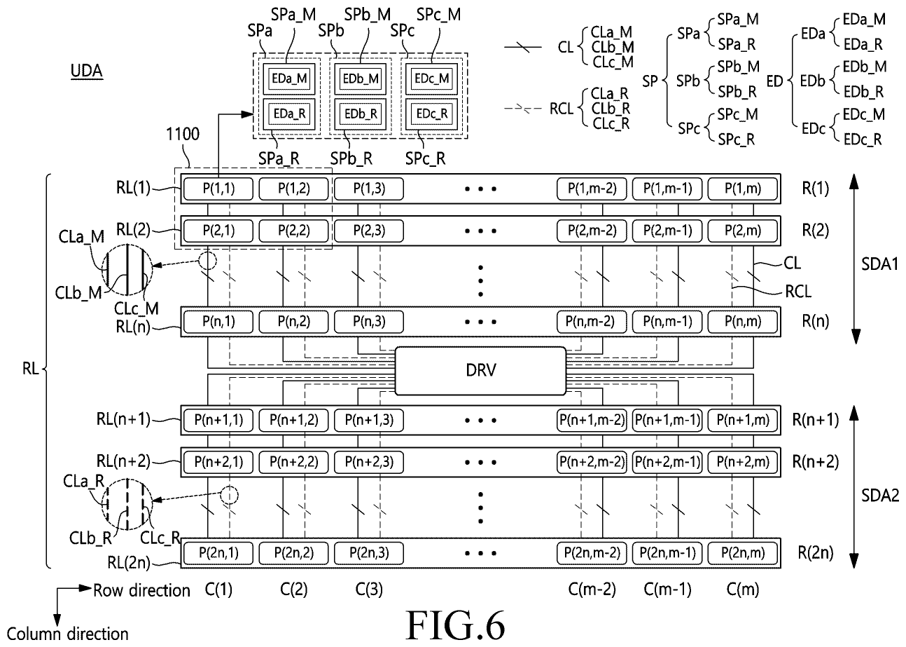

FIG. 6 illustrates a unit driving area UDA of a display panel 110 according to embodiments of the present disclosure.

Referring to FIG. 6, the display panel 110 according to embodiments of the present disclosure can include a plurality of pixels P, a plurality of row lines RL, and a plurality of column lines CL.

According to the example of FIG. 6, the plurality of pixels P can include pixels P(1, 1), . . . , P(1, m), P(2, 1), . . . , P(2, m), . . . , P(2n, 1), . . . , P(2n, m) of (2n×m) pixels arranged in the unit driving area UDA. The plurality of row lines RL can include 2n row lines RL(1) to RL(2n) arranged in the unit driving area UDA.

The display panel 110 according to the embodiments of the present disclosure can include a redundancy structure. According to the redundancy structure, each of the plurality of pixels P can include k main sub-pixels and k redundancy sub-pixels. Each of the k main sub-pixels can include a main light emitting device, and each of the k redundancy sub-pixels can include a redundancy light emitting device. In other words, each of the plurality of pixels P can include k main light emitting devices EDa_M, EDb_M and EDc_M and k redundancy light emitting devices EDa_R, EDb_R and EDc_R.

Each of the plurality of pixels P(1, 1), . . . , P(1, m), P(2, 1), . . . , P(2, m), . . . , P(2n, 1), . . . , P(2n, m) can include a first sub-pixel SPa, a second sub-pixel SPb, and a third sub-pixel SP.

The first sub-pixel SPa can include a first main sub-pixel SPa_M and a first redundancy sub-pixel SPa_R. The first main sub-pixel SPa_M can include a first main light emitting device EDa_M, and the first redundancy sub-pixel SPa_R can include a first redundancy light emitting device EDa_R.

The first sub-pixel SPa can include a first light emitting device EDa that emits a first color light, and the first light emitting device EDa can include a first main light emitting device EDa_M and a first redundancy light emitting device EDa_R.

The second sub-pixel SPb can include a second main sub-pixel SPb_M and a second redundancy sub-pixel SPb_R. The second main sub-pixel SPb_M can include a second main light emitting device EDb_M, and the second redundancy sub-pixel SPb_R can include a second redundancy light emitting device EDb_R.

The second sub-pixel SPb can include a second light emitting device EDb that emits second color light, and the second light emitting device EDb can include a second main light emitting device EDb_M and a second redundancy light emitting device EDb_R.

The third sub-pixel SPc can include a third main sub-pixel SPc_M and a third redundancy sub-pixel SPc_R. The third main sub-pixel SPc_M can include a third main light emitting device EDc_M, and the third redundancy sub-pixel SPc_R can include a third redundancy light emitting device EDc_R.

The third sub-pixel SPc can include a third light emitting device EDc that emits a third color light, and the third light emitting device EDc can include a third main light emitting device EDc_M and a third redundancy light emitting device EDc_R.

Referring to FIG. 6, the plurality of column lines CL can include a plurality of main column lines CLa_M, CLb_M and CLc_M and a plurality of redundancy column lines CLa_R, CLb_R and CLc_R.

In each of the plurality of columns (i.e., a plurality of pixel columns) included in each of the first sub-driving area (SDA and the second sub-driving area SDA2, k main column lines CLa_M, CLb_M and CLc_M, and k redundancy column lines CLa_R, CLb_R and CLc_R can be arranged.

In each column (i.e., each pixel column), k main column lines CLa_M, CLb_M and CLc_M can be connected to the first electrodes Ecl of k main light emitting devices EDa_M, EDb_M and EDc_M.

In each column (i.e., each pixel column), k redundancy column lines CLa_R, CLb_R and CLc_R can be connected to the first electrodes Ecl of k redundancy light emitting devices EDa_R, EDb_R and EDc_R.

Since this redundancy structure is configurations for repair, the redundancy configurations can be excluded from the display device.

Hereinafter, in order to examine the planar structure of the display panel 110 according to the embodiments of the present disclosure in more detail, it will be described the planar structure of a portion 1100 of the planar view of FIG. 6 in more detail as an example.

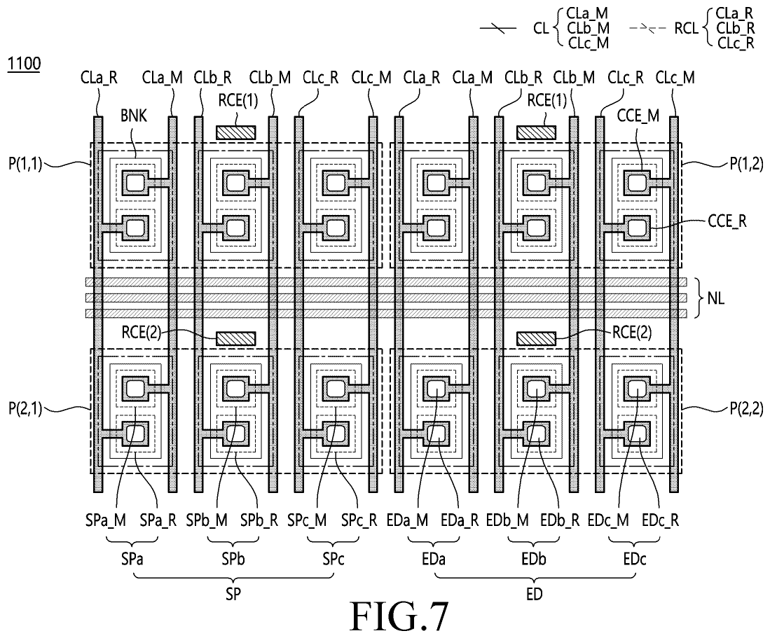

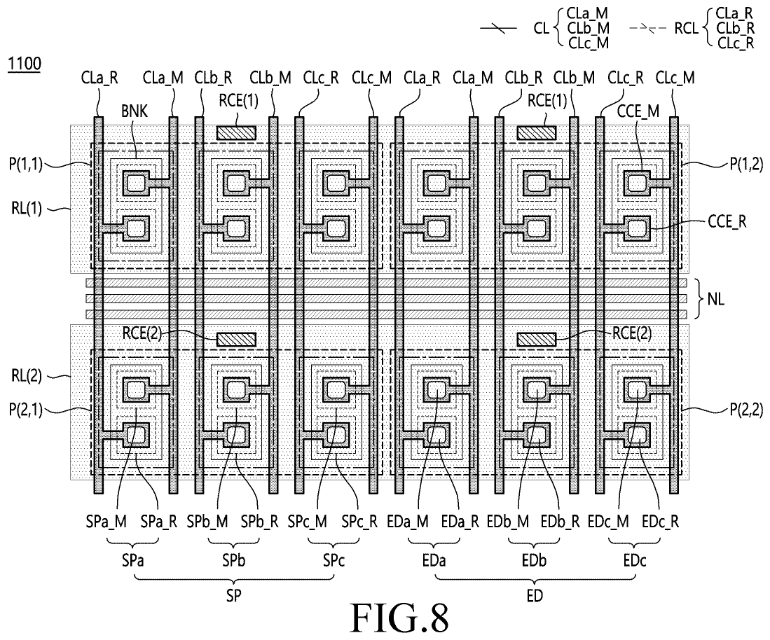

FIG. 7 and FIG. 8 are plan views of a portion 1100 of a display panel 110 according to embodiments of the present disclosure. FIG. 7 and FIG. 8 are enlarged plan views of a portion 1100 of the plan view of FIG. 6, and are enlarged plan views of a two-row, two-column area 1100.

Particularly, FIG. 7 is a plan view that does not represent two row lines RL(1) and RL(2) arranged in a two-row, two-column area 1100, and FIG. 8 is a plan view in which two rows and lines RL(1) and RL(2) arranged in a two-row, two-column area 1100 are added to a plan view of FIG. 6.

Referring to FIG. 7 and FIG. 8, in the two-row, two-column area 1100, four pixels P(1,1), P(1,2), P(2,1), P(2,2) can be arranged in two rows and two columns. For example, in the two-row, two-column area 1100, two pixels P(1,1) and P(1,2) can be arranged in a first row (e.g., a first pixel row), and two pixels P(2,1) and P(2,2) can be arranged in a second row (e.g., a second pixel row). In addition, two pixels P(1,1) and P(2,1) can be arranged in a first column (e.g., a first pixel column), and two pixels P(1,2) and P(2,2) can be arranged in a second column (e.g., a second pixel column).

In the two-row, two-column area 1100, each of the four pixels P(1,1), P(1,2), P(2,1) and P(2,2) arranged in two rows and two columns can include k sub-pixels. Here, k is the number of sub-pixels included in one pixel.

It is exemplified a case where k is 3 is as an example. Accordingly, in the two-row, two-column area 1100, each of the four pixels P(1,1), P(1,2), P(2,1) and P(2,2)) arranged in two rows and two columns can include three sub-pixels SPa, SPb and SPc. In the following description, it can be explained assuming the case where k is 3.

The three sub-pixels can include a first sub-pixel SPa including a first light emitting device EDa that emits a first color light, a second sub-pixel SPb including a second light emitting device EDb that emits a second color light, and a third sub-pixel SPc including a third light emitting device EDc that emits a third color light.

If the display panel 110 according to the embodiments of the present disclosure has a redundancy structure, the sub-pixel redundancy structure is as follows.

The first sub-pixel SPa can include a first main sub-pixel SPa_M including a first main light emitting device EDa_M and a first redundancy sub-pixel SPa_R including a first redundancy light emitting device EDa_R, the second sub-pixel SPb can include a second main sub-pixel SPb_M including a second main light emitting device EDb_M and a second redundancy sub-pixel SPb_R including a second redundancy light emitting device EDb_R, and the third sub-pixel SPc can include a third main sub-pixel SPc_M including a third main light emitting device EDc_M and a third redundancy sub-pixel SPc_R including a third redundancy light emitting device EDc_R.

If the display panel 110 according to the embodiments of the present disclosure has a redundancy structure, the light emitting device redundancy structure is as follows.

The first light emitting device EDa can include a first main light emitting device EDa_M that emits a first color light and a first redundancy light emitting device EDa_R that emits a first color light, the second light emitting device EDb can include a second main light emitting device EDb_M that emits a second color light and a second redundancy light emitting device EDb_R that emits a second color light, and the third light emitting device EDb can include a third main light emitting device EDc_M that emits a third color light and a third redundancy light emitting device EDc_R that emits a third color light.

In the two-row, two-column area 1100, a first row line RL(1) and a second row line RL(2) can be arranged. The first row line RL(1) can be arranged in the first row (i.e., the first pixel row), and the second row line RL(2) can be arranged in the second row (i.e., the second pixel row).

The first row line RL(1) can correspond to two pixels P(1,1) and P(1,2) arranged in the first row (or the first pixel row), and can correspond to three sub-pixels SPa, SPb and SPc included in each of the two pixels P(1,1) and P(1,2) arranged in the first row (or the first pixel row).

In terms of the sub-pixel redundancy structure, the first row line RL(1) can be connected to the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the first row (or the first pixel row).

At least a portion of the first row line RL(1) can overlap with the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the first row (or the first pixel row).

From the perspective of the light emitting device redundancy structure, the first row line RL(1) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

At least a part of the first row line RL(1) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

The second row line RL(2) can correspond to two pixels P(2,1) and P(2,2) arranged in a second row (or the second pixel row), and can correspond to three sub-pixels SPa, SPb and SPc included in each of the two pixels P(2,1) and P(2,2) arranged in the second row (or the second pixel row).

In terms of the sub-pixel redundancy structure, the second row line RL(2) can be connected to the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the second row (or the second pixel row).

At least a portion of the second row line RL(2) can overlap with the first main sub-pixel SPa_M, the first redundancy sub-pixel SPa_R, the second main sub-pixel SPb_M, the second redundancy sub-pixel SPb_R, the third main sub-pixel SPc_M, and the third redundancy sub-pixel SPc_R arranged in the second row (or the second pixel row).

In terms of the light emitting device redundancy structure, the second row line RL(2) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

At least a portion of the second row line RL(2) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

A plurality of column lines CL can be arranged in the two-row two-column area 1100. A plurality of column lines CL arranged in a two-row two-column area 1100 can include a plurality of first column lines CL connected to two pixels P(1,1) and P(2,1) arranged in a first column (or a first pixel column), and a plurality of second column lines CL connected to two pixels P(1,2) and P(2,2) arranged in a second column (or a second pixel column).

From the perspective of sub-pixel redundancy, a plurality of first column lines CL arranged in a first column (or first pixel column) can include a first main column line CLa_M that is commonly connected to a first main sub-pixel SPa_M included in each of two pixels P(1,1)and P(2,1) arranged in the first column (or first pixel column), and a first redundancy column line CLa_R that is commonly connected to a first redundancy sub-pixel SPa_R included in each of two pixels P(1,1) and P(2,1) arranged in the first column (or first pixel column).

The first main sub-pixel SPa_M included in each of the two pixels P(1,1) and P(2,1) arranged in the first column (or the first pixel column) can include a first main light emitting device EDa_M, and the first redundancy sub-pixel SPa_R included in each of the two pixels P(1,1) and P(2,1) arranged in the first column (or the first pixel column) can include a first redundancy light emitting device (EDa_R).

The first main column line CLa_M arranged in the first column (or the first pixel column) can be commonly connected to the first electrodes Ecl of the two first main light emitting devices EDa_M arranged in the first column (or the first pixel column).

The first redundancy column line CLa_R arranged in the first column (or the first pixel column) can be commonly connected to the first electrodes Ecl of two first redundancy light emitting devices EDa_R arranged in the first column (or the first pixel column).

In addition, the plurality of first column lines CL arranged in the first column (or the first pixel column) can further include a second main column line CLb_M commonly connected to a second main sub-pixel SPb_M included in each of the two pixels P(1,1) and P(2,1) arranged in the first column (or the first pixel column), and a second redundancy column line CLb_R commonly connected to a second redundancy sub-pixel SPb_R included in each of the two pixels P(1,1) and P(2,1) arranged in the first column (or the first pixel column).

The second main sub-pixel SPb_M included in each of the two pixels P(1,1) and P(2,1) arranged in the first column (or the first pixel column) can include a second main light emitting device EDb_M, and the second redundancy sub-pixel SPb_R included in each of the two pixels P(1,1) and P(2,1) arranged in the first column (or the first pixel column) can include a second redundancy light emitting device EDb_R.

The second main column line CLb_M arranged in the first column (or the first pixel column) can be commonly connected to the first electrodes Ecl of the two second main light emitting devices EDb_M arranged in the first column (or the first pixel column).

The second redundancy column line CLb_R arranged in the first column (or the first pixel column) can be commonly connected to the first electrodes Ecl of the two second redundancy light emitting devices EDb_R arranged in the first column (or the first pixel column).

In addition, the plurality of first column lines CL arranged in the first column (or the first pixel column) can further include a third main column line CLc_M commonly connected to the third main sub-pixel SPc_M included in each of the two pixels P(1,1) and P(2,1) arranged in the first column (or the first pixel column), and a third redundancy column line CLc_R commonly connected to the third redundancy sub-pixel SPc_R included in each of the two pixels P(1,1) and P(2,1) arranged in the first column (or the first pixel column).

The third main sub-pixel SPc_M included in each of the two pixels P(1,1) and P(2,1) arranged in the first column (or the first pixel column) can include a third main light emitting device EDc_M, and the third redundancy sub-pixel SPc_R included in each of the two pixels P(1,1) and P(2,1) arranged in the first column (or the first pixel column) can include a third redundancy light emitting device EDc_R.

The third main column line CLc_M arranged in the first column (or the first pixel column) can be commonly connected to the first electrodes Ecl of the two third main light emitting devices EDc_M arranged in the first column (or the first pixel column).

The third redundancy column line CLc_R arranged in the first column (or the first pixel column) can be commonly connected to the first electrodes Ecl of two third redundancy light emitting devices EDc_R arranged in the first column (or the first pixel column).

From the perspective of sub-pixel redundancy, a plurality of second column lines CL arranged in a second column (or second pixel column) can include a first main column line CLa_M that is commonly connected to a first main sub-pixel SPa_M included in each of two pixels P(1,2) and P(2,2) arranged in the second column (or second pixel column), and a first redundancy column line CLa_R that is commonly connected to a first redundancy sub-pixel SPa_R included in each of two pixels P(1,2) and P(2,2) arranged in the second column (or second pixel column).

The first main sub-pixel SPa_M included in each of the two pixels P(1,2) and P(2,2) arranged in the second column (or the second pixel column) can include a first main light emitting device EDa_M, and the first redundancy sub-pixel SPa_R included in each of the two pixels P(1,2) and P(2,2) arranged in the second column (or the second pixel column) can include a first redundancy light emitting device EDa_R.

The first main column line CLa_M arranged in the second column (or the second pixel column) can be commonly connected to the first electrodes Ecl of the two first main light emitting devices EDa_M arranged in the second column (or the second pixel column).

The first redundancy column line CLa_R arranged in the second column (or the second pixel column) can be commonly connected to the first electrodes Ecl of the two first redundancy light emitting devices EDa_R arranged in the second column (or the second pixel column).

In addition, the plurality of second column lines CL arranged in the second column (second pixel column) can further include a second main column line CLb_M commonly connected to a second main sub-pixel SPb_M included in each of two pixels P(1,2) and P(2,2) arranged in the second column (or second pixel column), and a second redundancy column line CLb_R commonly connected to a second redundancy sub-pixel SPb_R included in each of two pixels P(1,2) and P(2,2) arranged in the second column (or second pixel column).

The second main sub-pixel SPb_M included in each of the two pixels P(1,2) and P(2,2) arranged in the second column (or the second pixel column) can include a second main light emitting device EDb_M, and the second redundancy sub-pixel SPb_R included in each of the two pixels P(1,2) and P(2,2) arranged in the second column (or the second pixel column) can include a second redundancy light emitting device EDb_R.

The second main column line CLb_M arranged in the second column (or the second pixel column) can be commonly connected to the first electrodes Ecl of the two second main light emitting devices EDb_M arranged in the second column (or the second pixel column).

The second redundancy column line CLb_R arranged in the second column (or the second pixel column) can be commonly connected to the first electrodes Ecl of two second redundancy light emitting devices EDb_R arranged in the second column (or the second pixel column).

In addition, the plurality of first column lines CL arranged in the second column (or the second pixel column) can further include a third main column line CLc_M commonly connected to a third main sub-pixel SPc_M included in each of two pixels P(1,2) and P(2,2) arranged in the second column (or the second pixel column), and a third redundancy column line CLc_R commonly connected to a third redundancy sub-pixel SPc_R included in each of two pixels P(1,2) and P(2,2) arranged in the second column (or the second pixel column).

The third main sub-pixel SPc_M included in each of the two pixels P(1,2) and P(2,2) arranged in the second column (or the second pixel column) can include a third main light emitting device EDc_M, and the third redundancy sub-pixel SPc_R included in each of the two pixels P(1,2) and P(2,2) arranged in the second column (or the second pixel column) can include a third redundancy light emitting device EDc_R.

The third main column line CLc_M arranged in the second column (or the second pixel column) can be commonly connected to the first electrodes Ecl of the two third main light emitting devices EDc_M arranged in the second column (or the second pixel column).

The third redundancy column line CLc_R arranged in the second column (or the second pixel column) can be commonly connected to the first electrodes Ecl of two third redundancy light emitting devices EDc_R arranged in the second column (or the second pixel column).

In each of the first column (or the first pixel column) and the second column (or the second pixel column), each of the plurality of column lines CL can include at least one column connection electrode having a shape protruding above a bank BNK. For example, the at least one column connection electrode can be an electrode electrically connected to each of the plurality of column lines CL or a portion protruding from each of the plurality of column lines C.

Each of the first main column line CLa_M, the second main column line CLb_M, and the third main column line CLc_M can include a main column connection electrode CCE_M protruding above the bank BNK and extending above the bank BNK.

The first main light emitting devices EDa_M, the second main light emitting devices EDb_M, and the third main light emitting devices EDc_M can be arranged on the main column connection electrodes CCE_M arranged to extend above the bank BNK.

In each of the first column (or first pixel column) and the second column (or second pixel column), each of the first redundancy column line CLa_R, the second redundancy column line CLb_R, and the third redundancy column line CLc_R can include a redundancy column connection electrode CCE_R that protrudes toward the bank BNK and extends above the bank BNK.

On the redundancy column connection electrodes CCE_R arranged to extend above the bank BNK, the first redundancy light emitting devices EDa_R, the second redundancy light emitting devices EDb_R, and the third redundancy light emitting devices EDc_R can be arranged.

The main column connection electrodes CCE_M and the redundancy column connection electrodes CCE_R arranged in the first column (or the first pixel column) can be disposed between the first main column line CLa_M and the first redundancy column line CLa_R.

The main column connection electrodes CCE_M and the redundancy column connection electrodes CCE_R arranged in the second column (or the second pixel column) can be disposed between the second main column line CLb_M and the second redundancy column line CLb_R.

The main column connection electrodes CCE_M and the redundancy column connection electrodes CCE_R arranged in the third column (or the third pixel column) can be disposed between the third main column line CLc_M and the third redundancy column line CLc_R.

The display panel 110 according to the embodiments of the present disclosure can further include at least one row connection electrode for electrically connecting each of the plurality of row lines RL to the driver DRV.

The display panel 110 according to the embodiments of the present disclosure can further include at least one first row connection electrode RCE(1) connected to a first row line RL(1) arranged in a first row (or a first pixel row), and at least one second row connection electrode RCE(2) connected to a second row line RL(2) arranged in a second row (or a second pixel row).

The first row line RL(1) can be vertically overlapped with at least one first row connection electrode RCE(1), and the second row line RL(2) can be vertically overlapped with at least one second row connection electrode RCE(2).

The first row line RL(1) can be electrically connected to the row driver R-DRV of the corresponding driver DRV through at least one first row connection electrode RCE(1). The second row line RL(2) can be electrically connected to the row driver R-DR of the corresponding driver DRV through at least one second row connection electrode RCE(2).

According to embodiments of the present disclosure, a bank BNK can be arranged in each of a plurality of sub-pixels SP. The plurality of banks BNK can be structures on which a plurality of light emitting devices ED are mounted. When manufacturing a panel, in a transfer process for transferring a plurality of light emitting devices ED to a display device 100, a plurality of banks BNK can guide the positions of the plurality of light emitting devices ED. For example, when manufacturing a panel, a plurality of light emitting devices ED can be transferred onto a plurality of banks BNK in a transfer process of the plurality of light emitting devices ED. The plurality of banks BNK can be an organic insulating layer, a bank pattern, or a structure, but the embodiments of the present disclosure are not limited thereto.

The banks BNK of each of the plurality of sub-pixels SP can be arranged to be spaced apart from each other. The banks BNK of each of the plurality of sub-pixels SP can be configured to be separated from each other. Accordingly, the banks BNK of the first sub-pixel SPa, the second sub-pixel SPb, and the third sub-pixel SPc to which different types of light emitting devices ED are transferred can be easily identified.

The bank BNK of the first main sub-pixel SPa_M and the bank BNK of the first redundancy sub-pixel SPa_R can be connected to each other, or can be formed spaced apart from each other or separately. For example, considering the design of the transfer process requirements, the bank BNK of the first main sub-pixel SPa_M and the bank BNK of the first redundancy sub-pixel SPa_R, in which light emitting devices EDa_M, EDa_R of the same type (for example, types that emit the same color light) are arranged, can be connected to each other, or can be formed spaced apart from each other or separately. In addition, the bank BNK of the second main sub-pixel SPb_M and the bank BNK of the second redundancy sub-pixel SPb_R can be connected to each other, or can be formed spaced apart from each other or separately. The bank BNK of the third main sub-pixel SPc_M and the bank BNK of the third redundancy sub-pixel SPc_R can be connected to each other, or can be formed to be spaced apart from each other or separated from each other.

The bank BNK of the first main sub-pixel SPa_M and the first redundancy sub-pixel SPa_R, the bank BNK of the second main sub-pixel SPb_M and the second redundancy sub-pixel SPb_R, and the bank BNK of the third main sub-pixel SPc_M and the third redundancy sub-pixel SPc_R can be formed in various ways, and the embodiments of the present disclosure are not limited thereto.

For example, the plurality of banks BNK can be formed of an organic insulating material. The plurality of banks BNK can be formed of a single layer or multiple layers of an organic insulating material. For example, the plurality of banks BNK can be composed of a photo resist, a polyimide (PI), or an acrylic material, but the embodiments of the present disclosure are not limited thereto.

The plurality of row lines RL can be formed of a transparent conductive material, but the embodiments of the present disclosure are not limited thereto. The plurality of row lines RL can be composed of a transparent conductive material so that light emitted from the light emitting devices ED can be directed upward through the row lines RL. For example, the plurality of row lines RL can be composed of a transparent conductive material such as indium tin oxide (ITO), indium zinc oxide (IZO), indium gallium zinc oxide (IGZO), and the like, but the embodiments of the present disclosure are not limited thereto.

The plurality of column lines CL can be made of a conductive material. For example, the plurality of column lines CL can be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), but the embodiments of the present disclosure are not limited thereto. For another example, the plurality of column lines CL can have a multilayer structure of conductive materials. For example, the plurality of column lines CL can be made of a multilayer structure of titanium (Ti)/aluminum (Al)/titanium (Ti)/indium tin oxide (ITO), but the embodiments of the present disclosure are not limited thereto.

For example, if the light emitting device ED is a device manufactured through a semiconductor process, such as a micro LED, a plurality of light emitting devices ED can be formed on a wafer and the light emitting devices ED can be transferred to a substrate 210 of the display panel 110 to manufacture the display panel 110. In the process of transferring a plurality of light emitting devices ED having a microscopic size from the wafer to the substrate 210, various defects can occur. For example, a non-transfer defect can occur in which the light emitting device ED is not transferred in some sub-pixels SP, and a misalignment defect can occur in which the light emitting device ED is transferred out of its proper position due to an alignment error in other sub-pixels SP. In addition, the transfer process can proceed normally, but the transferred light emitting device ED itself can have a defect. Therefore, considering the defects (including non-transfer defects) that occur during the transfer process of the light emitting devices EDs, the main light emitting device and the redundancy light emitting device, which are light emitting devices of the same type (e.g., light emitting devices that emit light of the same color), can be transferred to one sub-pixel SP. A lighting test can be performed on the main light emitting device and the redundancy light emitting device of the same type, and it is possible to utilize only one of the main light emitting device and the redundancy light emitting device that is finally determined to be normal.

For example, the first main light emitting device EDa_M and the first redundancy light emitting device EDa_R can be transferred together to one first sub-pixel SPa, and the first main light emitting device EDa_M and the first redundancy light emitting device EDa_R can be inspected for defects. If, as a result of the inspection, both the first main light emitting device EDa_M and the first redundancy light emitting device EDa_R are determined to be normal, only the first main light emitting device EDa_M can be used, and the first redundancy light emitting device EDa_R can be not used. If, as a result of the inspection, only the first redundancy light emitting device EDa_R among the first main light emitting device EDa_M and the first redundancy light emitting device EDa_R is normal, the first main light emitting device EDa_M is not used, and only the first redundancy light emitting device EDa_R can be used. Accordingly, even if the same first main light emitting device EDa_M and the first redundancy light emitting device EDa_R are transferred to one first sub-pixel SPa, only one of the first main light emitting device EDa_M and the first redundancy light emitting device EDa_R can be used finally.

Accordingly, among the main light emitting device and the redundancy light emitting device arranged in one sub-pixel SP, the redundancy light emitting device can be a spare light emitting device transferred in preparation for a failure of the main light emitting device. In the event of a failure of the main light emitting device, the redundancy light emitting device can be used as a replacement. Therefore, by transferring the main light emitting device and the redundancy light emitting device together to one sub-pixel SP, it is possible to minimize or reduce the deterioration of display quality due to a defect in one of the main light emitting device and the redundancy light emitting device.

In the embodiments of the present disclosure, the first main sub-pixel SPa_M and the first redundancy sub-pixel SPa_R can also be referred to as a 1-1 sub-pixel and a 1-2 sub-pixel, respectively, the second main sub-pixel SPb_M and the second redundancy sub-pixel SPb_R can also be referred to as a 2-1 sub-pixel and a 2-2 sub-pixel, and the third main sub-pixel SPc_M and the third redundancy sub-pixel SPc_R can also be referred to as a 3-1 sub-pixel and a 3-2 sub-pixel, respectively.

In the embodiments of the present disclosure, the first main light emitting device EDa_M and the first redundancy light emitting device EDa_R can also be referred to as a 1-1 light emitting device and a 1-2 light emitting device, the second main light emitting device EDb_M and the second redundancy light emitting device EDb_R can also be referred to as a 2-1 light emitting device and a 2-2 light emitting device, and the third main light emitting device EDc_M and the third redundancy light emitting device EDc_R can also be referred to as a 3-1 light emitting device and a 3-2 light emitting device.

The display panel 110 according to the embodiments of the present disclosure can further include a plurality of communication lines NL. The plurality of communication lines NL can be arranged so as not to overlap with the metal layer in a vertical direction. For example, a plurality of communication lines NL can be arranged between a first row line RL(1) and a second row line RL(2.

For example, the plurality of communication lines NL can be wires for short-range communication such as NFC (Near Field Communication) and Bluetooth. The plurality of communication lines NL can serve as signal transmission wires and/or antennas, but the embodiments of the present disclosure are not limited thereto.

Referring to FIG. 8, the first row line RL(1) can be arranged above a plurality of light emitting devices arranged in the first row (or the first pixel row) and can be arranged in a bar shape overlapping with all of the plurality of light emitting devices arranged in the first row (or the first pixel row).

The second row line RL(2) can be arranged above the plurality of light emitting devices arranged in the second row (or the second pixel row), and can be arranged in a bar shape overlapping with all of the plurality of light emitting devices arranged in the second row (or the second pixel row).

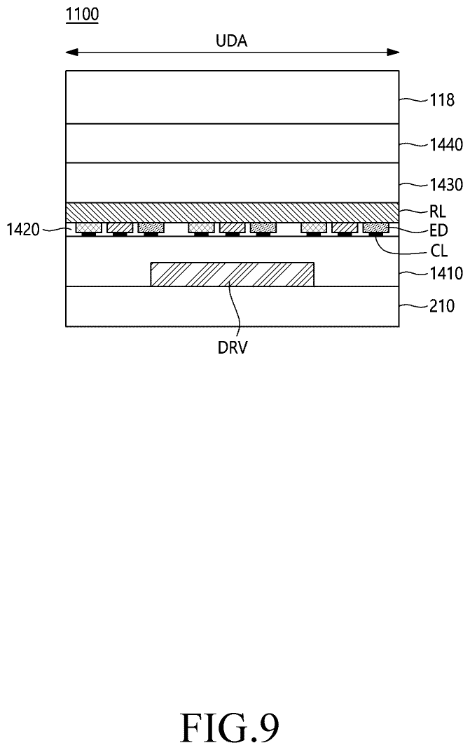

FIG. 9 is a cross-sectional view of a display panel 110 according to embodiments of the present disclosure. However, FIG. 9 is a cross-sectional view of a portion of a unit driving area UDA in which one driver DRV is arranged.

Referring to FIG. 9, a display panel 110 according to embodiments of the present disclosure can include a substrate 210, a driver DRV on the substrate 210, a layer stack 1410 on the driver DRV, a plurality of light emitting devices ED disposed on the layer stack 1410, an optical layer 1420 disposed on the layer stack 1410 and between the plurality of light emitting devices ED, an overcoat layer 1430 disposed on the plurality of light emitting devices ED and the optical layer 1420, an adhesive layer 1440 disposed on the overcoat layer 1430, and a cover member 118 disposed on the adhesive layer 1440.

The plurality of column lines CL can be arranged on a layer stack 1410. Each of the plurality of column lines CL can be arranged between the layer stack 1410 and a light emitting device ED. A plurality of row lines RL can be arranged on a plurality of light emitting devices ED and an optical layer 1420.

A display panel 110 according to embodiments of the present disclosure can include a substrate 210 including a display area DA, a plurality of light emitting devices ED arranged in the display area DA, a plurality of column lines CL electrically connected to first electrodes Ecl of each of the plurality of light emitting devices ED, a plurality of row lines RL electrically connected to second electrodes Erl of each of the plurality of light emitting devices ED, and a plurality of drivers DRV configured to drive the plurality of light emitting devices ED, the plurality of column lines CL, and the plurality of row lines RL.

A plurality of drivers DRV can be disposed in the display area DA, and can be positioned closer to the substrate 210 than the plurality of light emitting devices ED.

The layer stack 1410 can include a plurality of insulating layers. The plurality of insulating layers can include a plurality of organic layers. At least one of the plurality of organic layers can be arranged on a side of the driver DRV. For example, two or more organic layers can be arranged on a side of the driver DRV.

The layer stack 1410 can further include at least one metal layer connecting the driver DRV and the column line CL, and at least one metal layer connecting the driver DRV and the row line RL.

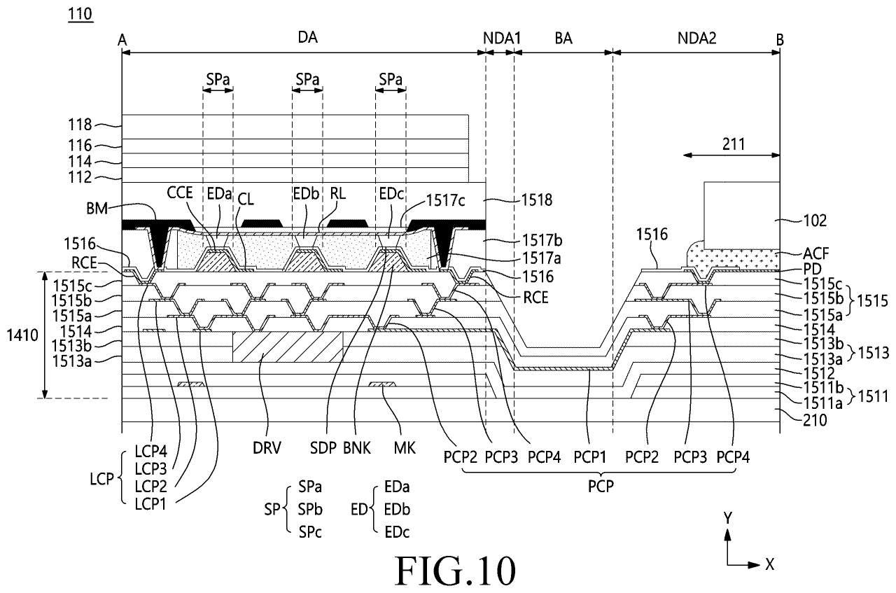

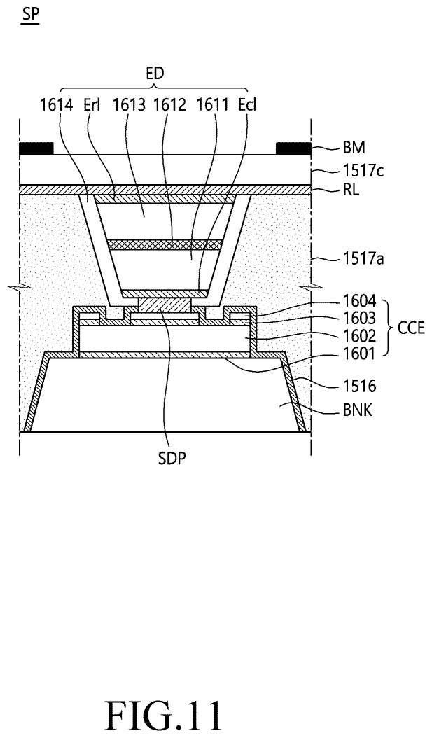

FIG. 10 is a detailed cross-sectional view of a display panel 110 according to embodiments of the present disclosure taken along the A-B cutting line of FIG. 5, and FIG. 11 is an enlarged cross-sectional view of a sub-pixel SP of a display panel 110 according to embodiments of the present disclosure. However, FIG. 10 is a cross-sectional view of a display area DA, a first non-display area NDA, a bending area BA, and a second non-display area NDA.

Meanwhile, for convenience of illustration, the A-B cutting line in FIG. 5 is illustrated as not overlapping with a signal line SL and a link line LL, but the A-B cutting line in FIG. 5 is intended to indicate the same position as the adjacent signal line SL and the link line LL.

Referring to FIG. 10, a buffer layer 1511 can be included on the substrate 210. The buffer layer 1511 can include a first buffer layer 1511a and a second buffer layer 1511b. The first buffer layer 1511a and the second buffer layer 1511b can be arranged in the display area DA, the first non-display area NDA1, and the second non-display area NDA, and may not be arranged in the entirety or part of the bending area BA. However, the present disclosure is not limited thereto.

The first buffer layer 1511a and the second buffer layer 1511b can reduce the penetration of moisture or impurities through the substrate 210. The first buffer layer 1511a and the second buffer layer 1511b can be made of an inorganic insulating material. For example, the first buffer layer 1511a and the second buffer layer 1511b can be composed of a single layer or multiple layers of silicon oxide (SiOx) or silicon nitride (SiNx), but the embodiments of the present disclosure are not limited thereto.

For example, a portion of the first buffer layer 1511a and the second buffer layer 1511b on the bending area BA can be removed. The upper surface of the substrate 210 located on the bending area BA can be exposed by the area (e.g., opening) where the first buffer layer 1511a and the second buffer layer 1511b are removed.

By removing the first buffer layer 1511a and the second buffer layer 1511b from the bending area BA, it is possible to minimize or reduce an occurrence of cracks in the first buffer layer 1511a and the second buffer layer 1511b that can occur during bending.

A plurality of alignment keys MK can be arranged between the first buffer layer 1511a and the second buffer layer 1511b. The plurality of alignment keys MK can be configured to identify the position of the driver DRV during the manufacturing process of the display panel 110. For example, the plurality of alignment keys MK can be configured to align the position of the driver DRV transferred on the adhesive layer 1512. In another example, the plurality of alignment keys MK can be omitted.

An adhesive layer 1512 can be disposed on the second buffer layer 1511b. The adhesive layer 1512 can be disposed in the display area DA, the first non-display area NDA1, the bending area BA, and the second non-display area NDA2. For another example, at least a portion of the adhesive layer 1512 can be removed in the non-display area NDA including the bending area BA. For example, the adhesive layer 1512 can be made of any one of an adhesive polymer, an epoxy resin, a UV-curable resin, a polyimide series, an acrylate series, a urethane series, and a polydimethylsiloxane (PDMS), but the embodiments of the present disclosure are not limited thereto.

A driver DRV can be disposed on the adhesive layer 1512 in the display area DA. If the driver DRV is implemented as a driving chip (e.g., driver integrated circuit), the driving driver can be mounted on the adhesive layer 1512 by a transfer process, but the embodiments of the present disclosure are not limited thereto.

The display panel 110 can further include a side protection layer 1513 disposed on the side of the plurality of drivers DRV, and an upper protection layer 1514 disposed on the plurality of drivers DRV and the side protection layer 1513.

The display panel 110 can further include a plurality of insulating layers 1515 disposed on the upper protection layer 1514.

According to embodiments of the present disclosure, in the display area DA, a plurality of line connection patterns LCP can be arranged on the second protection layer 1513b. The plurality of line connection patterns LCP can be wiring for electrically connecting the driver DRV to other components.

The display panel 110 can further include a side protection layer 1513 including at least one of the first protection layer 1513a and the second protection layer 1513b, and an upper protection layer 1514 arranged on the plurality of drivers DRV. For example, the upper protection layer 1514 can include a third protection layer 1514, and in some cases, can further include at least one additional protection layer. The third protection layer 1514 can be disposed on the second protection layer 1513b and the plurality of first line connection patterns LCP1. The third protection layer 1514 can be disposed entirely in the display area DA and the non-display area NDA. In the bending area BA, the third protection layer 1514 can cover or enclose the side surface of the second protection layer 1513b and the upper surface of the first protection layer 1513a.

A plurality of second line connection patterns LCP2 can be arranged on the third protection layer 1514. The plurality of second line connection patterns LCP2 can be electrically connected or directly connected to the driver DRV. For example, some of the second line connection patterns LCP2 can be directly or indirectly connected to the driver DRV through contact holes of the third protection layer 1514. Other parts of the second line connection patterns LCP2 can be electrically connected to the first line connection pattern LCP1 through contact holes of the third protection layer 1514. However, the embodiments of the present disclosure are not limited thereto. The voltage output from the driver DRV can be transmitted to the column line CL or the row line RL through the plurality of second line connection patterns LCP2 and other connection patterns.

A first insulating layer 1515a can be disposed on the plurality of second line connection patterns LCP2. The first insulating layer 1515a can be disposed entirely over the display area DA and the non-display area NDA, but the embodiments of the present disclosure are not limited thereto. The first insulating layer 1515a can be composed of an organic insulating material, but the embodiments of the present disclosure are not limited thereto.

A plurality of third line connection patterns LCP3 can be disposed on the first insulating layer 1515a. The plurality of third line connection patterns LCP3 can be electrically connected to the plurality of second line connection patterns LCP2.

A second insulating layer 1515b can be disposed on a plurality of third line connection patterns LCP3. The second insulating layer 1515b can be disposed in the display area DA, the first non-display area NDA1, and the second non-display area NDA2, and may not be disposed in the entirety or part of the bending area BA, but the embodiments of the present disclosure are not limited thereto.

A plurality of fourth line connection patterns LCP4 can be arranged on the second insulating layer 1515b. The plurality of fourth line connection patterns LCP4 can be electrically connected to a plurality of third line connection patterns LCP3.

According to the embodiments of the present disclosure, in the non-display area NDA, a plurality of pad connection patterns PCP can be arranged on the second protection layer 1513b. A plurality of pad connection patterns PCPs can be wiring for transmitting a signal transmitted from a flexible printed circuit 102 to a pad section 211 to a driver DRV of a display area DA.

The plurality of first pad connection patterns PCP1 can be arranged on the second protection layer 1513b. Each of the plurality of first pad connection patterns PCP1 can be arranged across the second non-display area NDA2, the bending area BA, and the first non-display area NDA1. Each of the plurality of first pad connection patterns PCP1 can include a first portion arranged in the bending area BA, a second portion extending from the first portion to the first non-display area NDA1, and a third portion extending from the first portion to the second non-display area NDA2. Each of the plurality of first pad connection patterns PCP1 can extend from the first non-display area NDA1 to a portion of the display area DA. The plurality of first pad connection patterns PCP1 can transmit a signal transmitted from the flexible printed circuit 102 to the pad portion 211 to the driver DRV of the display area DA.

Each of the plurality of first pad connection patterns PCP1 can be electrically connected to the pad PD of the pad section 211 through connection patterns arranged in the second non-display area NDA2. Here, the connection patterns electrically connecting each of the plurality of first pad connection patterns PCP1 to the pad PD can include at least one of the second pad connection pattern PCP2, the third pad connection pattern PCP3, and the fourth pad connection pattern PCP4 arranged in the second non-display area NDA2.

Each of the plurality of first pad connection patterns PCP1 can be electrically connected to the driver DRV through connection patterns arranged in the display area DA. Here, the connection patterns electrically connecting each of the plurality of first pad connection patterns PCP1 to the driver DRV can include at least one of the second pad connection pattern PCP2, the third pad connection pattern PCP3, and the fourth pad connection pattern PCP4 arranged in the display area DA.

The plurality of second pad connection patterns PCP2 can be arranged on the third protection layer 1514. The plurality of second pad connection patterns PCP2 can be arranged in the second non-display area NDA2. The second pad connection pattern PCP2 can be electrically connected to the first pad connection pattern PCP1 through a contact hole of the third protection layer 1514. Therefore, the signal supplied from the flexible printed circuit 102 can be transmitted to the first pad connection pattern PCP1 through the second pad connection pattern PCP.

The third pad connection pattern PCP3 can be arranged on the first insulating layer 1515a. The third pad connection pattern PCP3 can be arranged in the second non-display area NDA2. The third pad connection pattern PCP3 can be electrically connected to the second pad connection pattern PCP2 through a contact hole of the first insulating layer 1515a. Therefore, the signal supplied from the flexible printed circuit 102 can be transmitted to the second pad connection pattern PCP2 through the third pad connection pattern PCP3, and the signal transmitted to the second pad connection pattern PCP2 can be transmitted again to the first pad connection pattern PCP1.

The fourth pad connection pattern PCP4 can be arranged on the second insulating layer 1515b. The fourth pad connection pattern PCP4) can be arranged in the second non-display area NDA2. The fourth pad connection pattern PCP4 can be electrically connected to the third pad connection pattern PCP3 through a contact hole of the second insulating layer 1515b. The pad PD of the pad section 211 can be electrically connected to the fourth pad connection pattern PCP4 through a contact hole of the third insulating layer 1515c.

A signal supplied from a flexible printed circuit 102 is input to a pad PD of a pad section 211, and a signal input to the pad PD is transmitted to a third pad connection pattern PCP3 through a fourth pad connection pattern PCP4, and a signal transmitted to the third pad connection pattern PCP3 can be transmitted again to a first pad connection pattern PCP1 through a second pad connection pattern PCP2. A signal transmitted to the first pad connection pattern PCP1 can be transmitted to a driver DRV through connection patterns arranged in a display area DA.

Referring to FIG. 10, a plurality of line connection patterns LCP and a plurality of pad connection patterns PCP can be arranged in various metal layers. The plurality of line connection patterns LCP and the plurality of pad connection patterns PCP can be formed of any one of a conductive material having excellent ductility or various conductive materials used in a display area DA.

A third insulating layer 1515c can be disposed on the plurality of line connection patterns LCP and the plurality of pad connection patterns PCP. The third insulating layer 1515c is disposed in the display area DA, the first non-display area NDA1, and the second non-display area NDA2, and can be disposed in all or part of the bending area BA, but the embodiments of the present disclosure are not limited thereto. In the bending area BA, a part of the third insulating layer 1515c can be removed. The third insulating layer 1515c can be composed of an organic insulating material, but the embodiments of the present disclosure are not limited thereto.

A plurality of banks BNK can be disposed on the third insulating layer 1515c in the display area DA. The plurality of banks BNKs can be arranged to overlap with at least a portion of each of the plurality of sub-pixels SPa, SPb and SPc. For example, the first sub-pixel SPa can include a first light emitting device EDa that emits a first color light, the second sub-pixel SPb can include a second light emitting device EDb that emits a second color light, and the third sub-pixel SPc can include a third light emitting device EDc that emits a third color light.

As an example, one light emitting device ED can be arranged on top of each of the plurality of banks BNKs. As another example, two or more light emitting devices ED can be arranged on top of each of the plurality of banks BNK. The two or more light emitting devices EDs arranged on top of each of the plurality of banks BNK can be light emitting devices of the same type.

In the display area DA, a plurality of row connection electrodes RCE can be arranged on the third insulating layer 1515c. The plurality of row connection electrodes RCE can transfer a low-potential voltage VSS output from the driver DRV to the row line RL.

In the display area DA, a plurality of column lines CL can be arranged on the third insulating layer 1515c. The plurality of column lines CL can be arranged in an area between the plurality of banks BNK. For example, the plurality of column lines CL can be arranged adjacent to one of the plurality of banks BNK.

Each of the plurality of column lines CL can include a wiring portion and a column connection electrode CCE protruding from the wiring portion. The wiring portion and the column connection electrode CCE included in each of the plurality of column lines CL can be formed integrally or can be different metals that are electrically connected.

For example, each of the plurality of column lines CL can include a column connection electrode CCE that is a portion protruding above an adjacent bank BNK among the plurality of banks BNK. The column connection electrode CCE of each of the plurality of column lines CL can be arranged to extend along the side and upper surface of the bank BNK. The column connection electrode CCE can be an electrode electrically connected to each of the plurality of column lines CL or can be a portion protruding from each of the plurality of column lines CL.

Referring to FIG. 11, the column connection electrode CCE of the column line CL can be composed of one conductive layer or multiple conductive layers. For example, a column connection electrode CCE electrically connected to a column line CL or protruding from the column line CL can include a first conductive layer 1601, a second conductive layer 1602, a third conductive layer 1603, and a fourth conductive layer 1604, but the embodiments of the present disclosure are not limited thereto.

The first conductive layer 1601 can be disposed on a bank BNK. The second conductive layer 1602 can be disposed on the first conductive layer 1601. The third conductive layer 1603 can be disposed on the second conductive layer 1602, and the fourth conductive layer 1604 can be disposed on the third conductive layer 1603.

According to the embodiments of the present disclosure, among the plurality of conductive layers constituting the column connection electrode CCE, some conductive layers having good reflection efficiency can be configured as an alignment key and/or a reflector for aligning the light emitting devices ED. For example, among the plurality of conductive layers constituting the column connection electrode CCE, the second conductive layer 1602 can include a reflective material. For example, the second conductive layer 1602 can include aluminum (Al), but the embodiments of the present disclosure are not limited thereto. Accordingly, the second conductive layer 1602 can be configured as a reflector. In addition, due to the high reflection efficiency of the second conductive layer 1602, it can be easily identified in the manufacturing process, and thus the position or transfer position of the light emitting device ED can be aligned based on the second conductive layer 1602.

For example, in order to configure the second conductive layer 1602 as a reflector, the third conductive layer 1603 and the fourth conductive layer 1604 disposed on the second conductive layer 1602 can be partially removed or etched. For example, a portion of the third conductive layer 1603 and the fourth conductive layer 1604 disposed on the bank BNK can be removed or etched to expose the upper surface of the second conductive layer 1602. For example, the openings of the third conductive layer 1603 and the fourth conductive layer 1604 can overlap with a portion of the upper surface of the second conductive layer 1602. For example, in the third conductive layer 1603 and the fourth conductive layer 1604, the central portion and the edge portion where a solder pattern SDP is arranged can remain, and the remaining portions excluding this portion (e.g., the central portion, the edge portion) can be removed.

According to the embodiments of the present disclosure, the first conductive layer 1601 and the third conductive layer 1603 can include titanium (Ti) or molybdenum (Mo). The second conductive layer 1602 can include aluminum (Al). The fourth conductive layer 1604 can include a transparent conductive oxide layer such as indium tin oxide (ITO) or indium zinc oxide (IZO) that has good adhesion to the solder pattern SDP and corrosion resistance and acid resistance. However, the embodiments of the present disclosure are not limited thereto.

The first conductive layer 1601, the second conductive layer 1602, the third conductive layer 1603, and the fourth conductive layer 1604 can be sequentially deposited and then patterned by performing a photolithography process and an etching process, but the embodiments of the present disclosure are not limited thereto.

According to embodiments of the present disclosure, two or more of the column connection electrode CCE, the column line CL, the row connection electrode RCE, and the pad PD can be arranged on the same layer. The column connection electrode CCE, the column line CL, the row connection electrode RCE, and the pad PD can be composed of a single layer or multiple layers of a conductive material, but the embodiments of the present disclosure are not limited thereto.

According to embodiments of the present disclosure, a solder pattern SDP can be arranged on the column connection electrode CCE in each of a plurality of sub-pixels. The solder pattern SDP can bond the light emitting device ED to the column connection electrode CCE.

According to the embodiments of the present disclosure, the passivation layer 1516 can be disposed on a plurality of column lines CL, a plurality of column connection electrodes CCE, a plurality of row connection electrodes RCE, and a third insulating layer 1515c.

For example, the passivation layer 1516 can be disposed on a display area DA, a first non-display area NDA1, and a second non-display area NDA2. In the entirety or a portion of the bending area BA, at least a portion of the passivation layer 1516 covering the plurality of pads PD can be removed. A portion of the passivation layer 1516 covering the plurality of pads PD in the second non-display area NDA2 can be removed. In addition, as illustrated in FIG. 11, the passivation layer 1516 can be removed from the area where the solder pattern SDP is arranged.

Since the passivation layer 1516 is arranged to cover the remaining area except for the bending area BA, the plurality of pads PD, and the area where the solder pattern SDP is arranged, the penetration of moisture or impurities into the light emitting device ED can be reduced.

Referring to FIG. 11, the light emitting device ED can include a first electrode Ecl, a first semiconductor layer 1611, an active layer 1612, a second semiconductor layer 1613, a second electrode Erl, and an encapsulation film 1614, but the embodiments of the present disclosure are not limited thereto. For example, the encapsulation film 1614 may not be included in the light emitting device ED.

The first semiconductor layer 1611 can be disposed on the solder pattern SDP. The second semiconductor layer 1613 can be disposed on the first semiconductor layer 1611.

For example, one of the first semiconductor layer 1611 and the second semiconductor layer 1613 can be implemented as a compound semiconductor of group III-V, group II-VI, and can be doped with an impurity (or dopant). For example, one of the first semiconductor layer 1611 and the second semiconductor layer 1613 can be a semiconductor layer doped with an n-type impurity, and the other can be a semiconductor layer doped with a p-type impurity, but the embodiments of the present disclosure are not limited thereto.

For example, the first semiconductor layer 1611 and the second semiconductor layer 1613 can be a nitride semiconductor including an n-type impurity and a nitride semiconductor including a p-type impurity, respectively, but the embodiments of the present disclosure are not limited thereto. For example, the first semiconductor layer 1611 can be a nitride semiconductor containing a p-type impurity, and the second semiconductor layer 1613 can be a nitride semiconductor containing an n-type impurity, but the embodiments of the present disclosure are not limited thereto.

The active layer 1612 can be arranged between the first semiconductor layer 1611 and the second semiconductor layer 1613. The active layer 1612 can receive holes and electrons from the first semiconductor layer 1611 and the second semiconductor layer 1613 to emit light. For example, the active layer 1612 can be configured as one of a single well structure, a multi-well structure, a single quantum well structure, a multi-quantum well (MQW) structure, a quantum dot structure, and a quantum wire structure, but the embodiments of the present disclosure are not limited thereto. For example, the active layer 1612 can be configured as indium gallium nitride (InGaN) or gallium nitride (GaN), but the embodiments of the present disclosure are not limited thereto.

For another example, the active layer 1612 can include a multi-quantum well (MQW) structure having a well layer and a barrier layer having a higher band gap than the well layer. For example, the active layer 1612 can be formed of InGaN as a well layer and an AlGaN layer as a barrier layer, but the embodiments of the present disclosure are not limited thereto.

The first electrode Ecl of the light emitting device ED can be arranged between the first semiconductor layer 1611 and the solder pattern SDP. For example, the first electrode Ecl of the light emitting device ED can electrically connect the first semiconductor layer 1611 and the column connection electrode CCE. The column line voltage (e.g., the anode voltage) output from the driver DRV can be applied to the first semiconductor layer 1611 through the column line CL, the column connection electrode CCE, and the first electrode Ecl. For example, the first electrode Ecl can be composed of a conductive material capable of eutectic bonding with the solder pattern SDP, but the embodiments of the present disclosure are not limited thereto.

The second electrode Erl of the light emitting device ED can be disposed on the second semiconductor layer 1613. For example, the second electrode Erl of the light emitting device ED can electrically connect the second semiconductor layer 1613 and the row line RL. A row line voltage (e.g., referred to as a low-potential voltage VSS as a cathode voltage) output from the driver DRV can be applied to the second semiconductor layer 1613 through the row connection electrode RCE, the row line RL, and the second electrode Erl. The second electrode Erl of the light emitting device ED can be made of a transparent conductive material so that light emitted from the light emitting device ED can be directed to the upper portion of the light emitting device ED, but the embodiments of the present disclosure are not limited thereto. For example, the second electrode Erl can be made of a material such as indium tin oxide (ITO), indium zinc oxide (IZO), or indium gallium zinc oxide (IGZO), but the embodiments of the present disclosure are not limited thereto.

The encapsulation film 1614 can be disposed on at least a portion of the first semiconductor layer 1611, the active layer 1612, the second semiconductor layer 1613, the first electrode Ecl, and the second electrode Erl. For example, the encapsulation film 1614 can surround at least a portion of the first semiconductor layer 1611, the active layer 1612, the second semiconductor layer 1613, the first electrode Ecl, and the second electrode Erl.

For example, the encapsulation film 1614 can protect the first semiconductor layer 1611, the active layer 1612, and the second semiconductor layer 1613. For example, the encapsulation film 1614 can be disposed on a side surface of the first semiconductor layer 1611, a side surface of the active layer 1612, and a side surface of the second semiconductor layer 161.

For example, the encapsulation film 1614 can be disposed on at least a portion of the first electrode Ecl and the second electrode Erl of the light emitting device ED. For example, the encapsulation film 1614 can be disposed on an edge portion (or one side) of the first electrode Ecl of the light emitting device ED and an edge portion (or one side) of the second electrode Erl of the light emitting device ED. At least a portion of the first electrode Ecl can be exposed from the encapsulation film 1614 so that the first electrode Ecl can be connected to the solder pattern SDP. For example, at least a portion of the second electrode Erl can be exposed from the encapsulation film 1614 so that the second electrode Erl can be connected to the row line RL. For example, the encapsulation film 1614 can be made of an insulating material such as silicon nitride (SiNx) or silicon oxide (SiOx), but the embodiments of the present disclosure are not limited thereto.

For another example, the encapsulation film 1614 can have a structure in which a reflective material is dispersed in a resin layer, but the embodiments of the present disclosure are not limited thereto. For example, the encapsulation film 1614 can be manufactured as a reflector of various structures, but the embodiments of the present disclosure are not limited thereto. Light emitted from the active layer 1612 can be reflected upward by the encapsulation film 1614, thereby improving light extraction efficiency. For example, the encapsulation film 1614 can be a reflective layer, but the embodiments of the present disclosure are not limited thereto.

According to the embodiments of the present disclosure, the light emitting device ED is described as having a vertical structure, but the embodiments of the present disclosure are not limited thereto. For example, the light emitting device ED can have a lateral structure or a flip chip structure.

The structure of the light emitting device ED illustrated in FIG. 11 can be substantially equally applied to all of the first light emitting device EDa, the second light emitting device EDb, and the third light emitting device EDc. According to embodiments of the present disclosure, a first optical layer 1517a can be arranged to surround a plurality of light emitting devices ED in the display area DA. For example, the first optical layer 1517a can be arranged to cover a plurality of light emitting devices ED and the bank BNK in the area of a plurality of sub-pixels SP. For example, the first optical layer 1517a can cover a bank BNK, a portion of the passivation layer 1516, and a region between the plurality of light emitting devices ED. The first optical layer 1517a can be arranged or covered between a plurality of light emitting devices ED included in one pixel and between a plurality of banks BNK. For example, the first optical layer 1517a can be arranged to extend in the first direction (X) and be spaced apart from each other in the second direction (Y). For example, the first optical layer 1517a can be arranged to surround the side of the light emitting devices ED and the banks BNK between the passivation layer 1516 and the row line RL, but the embodiments of the present disclosure are not limited thereto. For example, the first optical layer 1517a can be a diffusion layer or a sidewall diffusion layer, but the embodiments of the present disclosure are not limited thereto.

The first optical layer 1517a can include an organic insulating material having fine particles dispersed therein, but the embodiments of the present disclosure are not limited thereto. For example, the first optical layer 1517a can be composed of siloxane having fine metal particles, such as titanium dioxide (TiO2) particles, dispersed therein, but the embodiments of the present disclosure are not limited thereto. Light from a plurality of light emitting devices ED can be scattered by the fine particles dispersed in the first optical layer 1517a and emitted to the outside of the display device 100. Accordingly, the first optical layer 1517a can improve the extraction efficiency of light emitted from the plurality of light emitting devices ED.

For example, the first optical layer 1517a can be arranged on each of a plurality of pixels, or can be arranged together on some pixels arranged in the same row, but the embodiments of the present disclosure are not limited thereto. For example, the first optical layer 1517a can be arranged on each of a plurality of pixels, or the plurality of pixels can share one first optical layer 1517a. For another example, each of the plurality of sub-pixels can separately include a first optical layer 1517a, but the embodiments of the present disclosure are not limited thereto.

According to the embodiments of the present disclosure, in the display area DA, a second optical layer 1517b can be arranged on the passivation layer 1516. For example, the second optical layer 1517b can be arranged to surround the first optical layer 1517a. For example, the second optical layer 1517b can be in contact with a side surface of the first optical layer 1517a. For example, the second optical layer 1517b can be arranged in an area between the plurality of pixels. However, the embodiments of the present disclosure are not limited thereto. For example, the second optical layer 1517b can be a diffusion layer, a diffusion layer window, or a window diffusion layer, but the embodiments of the present disclosure are not limited thereto.

The second optical layer 1517b can be composed of an organic insulating material, but the embodiments of the present disclosure are not limited thereto. The second optical layer 1517b can be composed of the same material as the first optical layer 1517a, but the embodiments of the present disclosure are not limited thereto. For example, the first optical layer 1517a can include fine particles, and the second optical layer 1517b may not include fine particles. For example, the second optical layer 1517b can be composed of siloxane, but the embodiments of the present disclosure are not limited thereto.

For example, the thickness of the first optical layer 1517a can be smaller than the thickness of the second optical layer 1517b, but the embodiments of the present disclosure are not limited thereto. Accordingly, when viewed from a planar view, the area where the first optical layer 1517a is disposed can include a concave portion that is sunken inwardly from the upper surface of the second optical layer 1517b.

According to the embodiments of the present disclosure, a row line RL can be disposed on the first optical layer 1517a and the second optical layer 1517b. For example, the row line RL can be electrically connected to a plurality of row connection electrodes RCE through contact holes of the second optical layer 1517b. For example, the row line RL can be disposed on a plurality of light emitting devices ED. For example, the row line RL can include a transparent conductive oxide such as indium tin oxide (ITO) or indium zinc oxide (IZO), but the embodiments of the present disclosure are not limited thereto. For example, the row line RL can be arranged to be in contact with the second electrode Erl of the light emitting device ED. For example, the row line RL can overlap with the first optical layer 1517a. For example, the row line RL can cover a plane on the outside of the first optical layer 1517a.

The row line RL can extend continuously in the first direction (X) of the substrate 210. Accordingly, the row line RL can be commonly connected to a plurality of pixels arranged in the first direction (X) of the substrate 210. For example, the row line RL can be commonly connected to a plurality of pixels.

According to the embodiments of the present disclosure, the row line RL can be continuously extended on the first optical layer 1517a, the second optical layer 1517b, and the light emitting device ED. The area where the first optical layer 1517a is disposed can include a concave portion that is sunken inwardly from the upper surface of the second optical layer 1517b. Accordingly, the first part of the row line RL disposed on the first optical layer 1517a can be disposed along the concave portion, and thus can be disposed at a lower position than the second part of the row line RL disposed on the second optical layer 1517b.

A third optical layer 1517c can be disposed on the row line RL. The third optical layer 1517c can be disposed so as to overlap with a plurality of light emitting devices ED and the first optical layer 1517a. Since the third optical layer 1517c is arranged on the row line RL and the plurality of light emitting devices ED, it is possible to improve a mura that can occur in some of the plurality of light emitting devices ED. For example, when transferring a plurality of light emitting devices ED onto the substrate 210 of the display panel 110, there can occur an area where the spacing between the plurality of light emitting devices ED is not uniform due to process deviation. If the spacing between the plurality of light emitting devices ED is not uniform, an emission areas of each of the plurality of light emitting devices ED can be arranged unevenly, and thus a mura can be visible to the user. Accordingly, since the third optical layer 1517c is arranged to uniformly diffuse light over the plurality of light emitting devices ED, it is possible to reduce light emitted from some of the light emitting devices ED from being visible as a mura. Accordingly, since the light emitted from the plurality of light emitting devices EDs is evenly diffused by the third optical layer 1517c and extracted to the outside of the display device 100, the luminance uniformity of the display device 100 can be improved.

The third optical layer 1517c can be composed of an organic insulating material in which fine particles are dispersed, but the embodiments of the present disclosure are not limited thereto. For example, the third optical layer 1517c can be composed of siloxane in which fine metal particles such as titanium dioxide (TiO2) particles are dispersed, but the embodiments of the present disclosure are not limited thereto. For example, the third optical layer 1517c can be composed of the same material as the first optical layer 1517a, but the embodiments of the present disclosure are not limited thereto. For example, the third optical layer 1517c can be a diffusion layer or an upper diffusion layer, but the embodiments of the present disclosure are not limited thereto.

According to the embodiments of the present disclosure, light from a plurality of light emitting devices ED can be scattered by fine particles dispersed in a third optical layer 1517c and emitted to the outside of the display device 100. The third optical layer 1517c can evenly mix light emitted from a plurality of light emitting devices ED, thereby further improving the luminance uniformity of the display device 100. In addition, the light extraction efficiency of the display device 100 can be improved by the light scattered from the plurality of fine particles, thereby enabling the display device 100 to be driven at low power.

A black matrix BM can be arranged on the row line RL, the first optical layer 1517a, the second optical layer 1517b, and the third optical layer 1517c in the display area DA. For example, the black matrix BM can fill a contact hole of the second optical layer 1517b. The black matrix BM can be configured to cover the display area DA, so that the color mixing of light and external light reflection of the plurality of sub-pixels can be reduced. For example, the black matrix BM can also be arranged in the contact hole where the row line RL and the row connection electrode RCE are connected, so that light leakage between the neighboring plurality of sub-pixels can be prevented or reduced.

A cover layer 1518 can be arranged on the black matrix BM in the display area DA. The cover layer 1518 can protect a configuration under the cover layer 1518. For example, the cover layer 1518 can be composed of an organic insulating material, but the embodiments of the present disclosure are not limited thereto.

A polarizing layer 114 can be arranged on the cover layer 1518 via a first adhesive layer 112. A cover member 118 can be arranged on the polarizing layer 114 via a second adhesive layer 116.

According to embodiments of the present disclosure, a plurality of pads PD can be arranged on a third insulating layer 1515c in a second non-display area NDA2. For example, at least a portion of the plurality of pads PD can be exposed from a passivation layer 1516. For example, the plurality of pads PD can be electrically connected to a fourth pad connection pattern PCP4 through a contact hole of the third insulating layer 1515c.

An adhesive layer ACF can be arranged on the plurality of pads PD. The adhesive layer ACF can be an adhesive layer in which conductive balls are dispersed in an insulating material, but embodiments of the present disclosure are not limited thereto. When heat or pressure is applied to the adhesive layer ACF, the conductive balls can be electrically connected at a portion where the heat or pressure is applied, thereby having conductive properties. The adhesive layer ACF can be disposed between a plurality of pads PD and a flexible printed circuit 102, so that the flexible printed circuit 102 can be attached or bonded to the plurality of pads PD. For example, the adhesive layer ACF can be an anisotropic conductive film ACF, but the embodiments of the present disclosure are not limited thereto.

A flexible printed circuit 102 can be disposed on the adhesive layer ACF. The flexible printed circuit 102 can be electrically connected to the plurality of pads PD through the adhesive layer ACF. Accordingly, a signal supplied from the flexible printed circuit 102 can be transmitted to a driver DRV of a display area DA through the plurality of pads PD, the fourth pad connection pattern PCP4, the third pad connection pattern PCP3, the second pad connection pattern PCP2, and the first pad connection pattern PCP1.

Referring to FIG. 10, the display panel 110 according to the embodiments of the present disclosure can include a substrate 210, a layer stack 1410 on a plurality of drivers DRV disposed on the substrate 210, an optical layer 1517a disposed between a plurality of light emitting devices EDa, EDb and EDc on the layer stack 1410, an adhesive layer 116 disposed on the plurality of light emitting devices EDa, EDb and EDc and the optical layer 1517a, and a cover member 118 disposed on the adhesive layer 116.

A plurality of column lines CL can be disposed between the layer stack 1410 and the plurality of light emitting devices EDa, EDb and EDc.

A plurality of row lines RL can be arranged on a plurality of light emitting devices EDa, EDb and EDc and an optical layer 1517a. A plurality of row lines RL can be arranged between a plurality of light emitting devices EDa, EDb and EDc, an optical layer 1517a, and an adhesive layer 116.

A layer stack 1410 can include a plurality of protection layers 1513a, 1513b and 1514 arranged on the side and upper surface of each of a plurality of drivers DRV, a plurality of insulating layers 1515a, 1515b and 1515c arranged on the plurality of protection layers 1513a, 1513b and 1514, and a bank BN arranged on the plurality of insulating layers.

The plurality of protection layers 1513a, 1513b and 1514 can further include a side protection layer 1513 disposed on each side of the plurality of drivers DRV and an upper protection layer 1514 disposed on the upper surface of each of the plurality of drivers DR.

The side protection layer 1513 can include a first protection layer 1513a disposed on the substrate 210 and a second protection layer 1513b disposed on the first protection layer 1513a.

The upper protection layer 1514 can include a second protection layer 1513b and a third protection layer 1514 disposed on the plurality of drivers DRV.

The plurality of insulating layers 1515a, 1515b and 1515c can include a first insulating layer 1515a disposed on the upper protection layer 1514, and a second insulating layer 1515b disposed on the first insulating layer 1515a. The plurality of insulating layers 1515a, 1515b and 1515c can further include a third insulating layer 1515c disposed on the second insulating layer 1515b.

Each of the plurality of light emitting devices EDa, EDb and EDc can be disposed on the bank BNK and positioned in an opening of the optical layer 1517a.

At least a portion of each of the plurality of column lines CL can extend onto the bank BNK on the plurality of insulating layers 1515a, 1515b and 1515c. Each of the plurality of row lines RL can be arranged on the optical layer 1517a and the plurality of light emitting devices EDa, EDb and EDc.

A first electrode Ecl of each of the plurality of light emitting devices EDa, EDb and EDc can be electrically connected to at least a portion of a column line CL extending onto the bank BNK among the plurality of column lines CL. A second electrode Erl of each of the plurality of light emitting devices EDa, EDb and EDc can be electrically connected to one of the plurality of row lines RL.

The display panel 110 according to the embodiments of the present disclosure can include a plurality of line connection patterns LCPs that connect each of a plurality of lines including a plurality of row lines RL and a plurality of column lines CL to a plurality of drivers DR.

The plurality of line connection patterns LCPs can include a first line connection pattern LCP1 disposed on a side protection layer 1513, a second line connection pattern LCP2 disposed on an upper protection layer 1514 and electrically connected to the first line connection pattern LCP1 through a hole in the upper protection layer 1514, a third line connection pattern LCP3 disposed on a first insulating layer 1515a and electrically connected to the second line connection pattern LCP2 through a hole in the first insulating layer 1515a, and a fourth line connection pattern LCP4 disposed on a second insulating layer 1515b and electrically connected to the third line connection pattern LCP3 through a hole in the second insulating layer 1515b.

The first line connection pattern LCP1 can be electrically connected to one of the plurality of drivers DRV. The fourth line connection pattern LCP4 can be electrically connected to at least one second electrode Erl of the plurality of light emitting devices EDa, EDb and EDc, or can be electrically connected to at least one first electrode Ecl of the plurality of light emitting devices EDa, EDb and EDc.

The side protection layer 1513 arranged on each side of the plurality of drivers DRV can include two or more organic layers.

The first and second protection layers 1513a and 1513b as the side protection layer 1513, the third protection layer 1514 as the upper protection layer 1514, and the first to third insulating layers 1515a, 1515b and 1515c can each be composed of organic layers.

In the above, there have been described the structure and operation related to the display function of the display device 100 according to the embodiments of the present disclosure.

The display device 100 according to the embodiments of the present disclosure can provide not only a display function but also a touch sensing function. Accordingly, hereinafter, it will be described a structure and an operation related to the touch sensing function of the display device 100 according to the embodiments of the present disclosure.

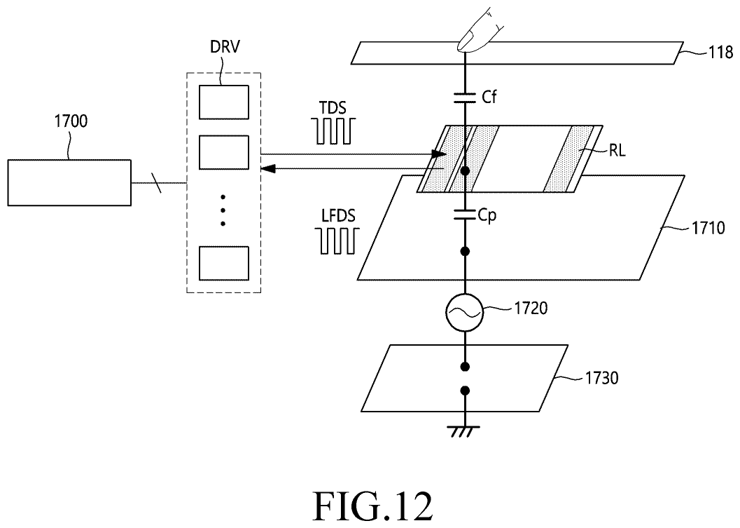

FIG. 12 briefly illustrates a touch sensing structure of a display device according to embodiments of the present disclosure.

Referring to FIG. 12, the display device 100 according to the embodiments of the present disclosure can include a plurality of row lines RL that serve as touch sensors to perform touch sensing, a plurality of drivers DRV for driving and sensing the plurality of row lines RL, and a touch control circuit 1700 that controls the plurality of drivers DRV.

The plurality of drivers DRV can supply a touch driving signal TDS having a variable voltage level to at least one of the plurality of row lines RL.

The touch driving signal TDS is a signal whose voltage level fluctuates, and can also be referred to as an AC signal or a pulse signal.

A plurality of drivers DRV can sense or detect an electrical state (e.g., a capacitance change) in at least one of a plurality of row lines RL to generate sensing data, and output the generated sensing data. Here, the sensing data can include digital sensing values.

The plurality of drivers DRV can include at least one analog-to-digital converter ADC to sense an electrical state in at least one of the plurality of row lines RL to obtain digital sensing values.

For example, the electrical state in at least one of the plurality of row lines RL can include a capacitance Cf between a touch object such as a finger or a pen and each row line RL. For another example, the electrical state in at least one of the plurality of row lines RL can include a capacitance between two row lines RL.

The touch control circuit 1700 can supply a touch driving signal TDS or a signal as a base of the touch driving signal TDS to each of the plurality of drivers DRV, and determine an occurrence of a touch or a touch position based on sensing data provided from each of the plurality of drivers RV.

If a touch driving signal TDS is applied to at least one of a plurality of row lines RL for touch sensing, an unwanted parasitic capacitance Cp can be formed between the row line RL supplied with the touch driving signal TDS and other electrodes or other wirings around the corresponding row line RL. The parasitic capacitance Cp can be a factor causing a reduction of the touch sensitivity.

The display device 100 according to the embodiments of the present disclosure can further include a touch ground 1710 arranged below the plurality of row lines RL. The touch ground 1710 can correspond to an electrode that forms a parasitic capacitance Cp with the row line RL.

The display device 100 according to the embodiments of the present disclosure can further include a guard driver 1720 that supplies a load-free driving signal LFDS whose signal characteristics correspond to the touch driving signal TDS to the touch ground 1710 in order to prevent or reduce an unwanted parasitic capacitance Cp from being formed between the row line RL and the touch ground 1710.

The load-free driving signal LFDS output from the guard driver 1720 applied to the touch ground 1710 can be a signal whose signal characteristics are similar to the touch driving signal TDS output from the driver DRV and supplied to the row line RL. For example, the signal characteristics can include frequency, amplitude, and phase. For example, the load-free driving signal LFDS can have the same frequency as the touch driving signal TDS. The load-free driving signal LFDS can have the same amplitude as the touch driving signal TDS. The load-free driving signal LFDS can have the same phase as the touch driving signal TDS.

The display device 100 according to the embodiments of the present disclosure can further include a system ground 1730 that serves as a ground for the entire system.

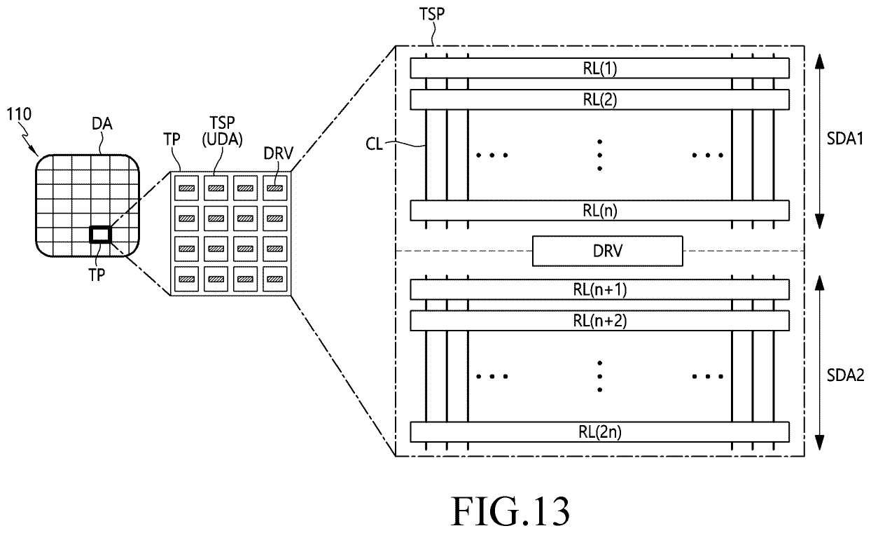

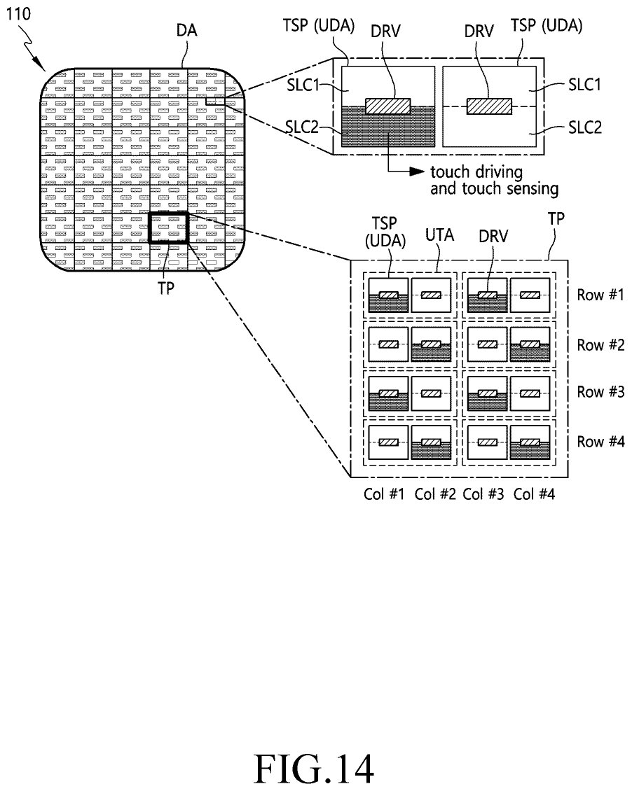

FIGS. 13 and 14 illustrate a touch driving structure of a display panel 110 according to embodiments of the present disclosure. FIGS. 1 to 12 are also referred to in the following description.

Referring to FIGS. 13 and 14, the display area DA of the display panel 110 can include a plurality of touch pixel areas TP. Each of the plurality of touch pixel areas TP can be an area corresponding to one touch electrode TE.

Each of the plurality of touch pixel areas TP can include a plurality of touch sub-pixel areas TSP. According to the examples of FIGS. 13 and 14, each of the plurality of touch pixel areas TP can include 16 touch sub-pixel areas TSP. The 16 touch sub-pixel areas TSP can be arranged in four rows and four columns.

Each of the plurality of touch sub-pixel areas TSP can include one of the plurality of drivers DRV. For example, one driver DRV can be disposed in one touch sub-pixel area TSP. One touch sub-pixel area TSP can correspond to one unit driving area UDA.

Each of the plurality of touch sub-pixel areas TSP can include a plurality of row lines RL(1) to RL(2n), (where n is a natural number greater than or equal to 1) and a plurality of column lines CL. Each of the plurality of touch sub-pixel areas TSP can include a plurality of sub-pixels SP. Each of the plurality of touch sub-pixel areas TSP can include a plurality of light emitting devices ED.

Each of the plurality of touch sub-pixel areas TSP can include a first sub-driving area SDA1 and a second sub-driving area SDA2. The first sub-driving area SDA1 can include two or more row lines RL(1) to RL(n) and two or more column lines CL. The second sub-driving area SDA2 can include two or more row lines RL(n+1) to RL(2n) and two or more column lines CL.

A plurality of row lines RL arranged in one touch pixel area TP corresponding to one touch electrode and simultaneously performing touch driving can be processed as one touch electrode TE in the touch control circuit 1700 even if they are driven and sensed by a plurality of drivers DRV. For example, a plurality of row lines RL arranged in one touch pixel area TP and simultaneously performing touch driving can be recognized as one touch electrode TE electrically connected to each other.

The touch control circuit 1700 can determine an occurrence of the touch and/or a touch coordinate by considering the integrated sensing data SEN_DATA obtained from each of the plurality of row lines RL arranged in one touch pixel area TP and simultaneously performing touch driving as sensing data obtained from one touch electrode TE.

Referring to FIG. 14, each of the plurality of touch pixel areas TP can include two or more unit touch driving areas UTA. Each of the two or more unit touch driving areas UTA can include at least one touch sub-pixel area TSP. According to the example of FIG. 14, each of the two or more unit touch driving areas UTA can include two touch sub-pixel areas TSP. Here, the unit touch driving area UTA is an area that becomes a basic unit of a touch driving pattern.

One touch sub-pixel area TSP corresponding to one unit driving area UDA can include two sub-touch driving areas SLC1 and SLC2. The two sub-touch driving areas can include a first sub-touch driving area SLC1 and a second sub-touch driving area SLC2. For example, the first sub-touch driving area SLC1 can correspond to an upper area in one touch sub-pixel area TSP, and the second sub-touch driving area SLC2 can correspond to a lower area in one touch sub-pixel area TSP. However, embodiments of the present disclosure are not limited thereto.

Two or more row lines RL and two or more column lines CL can be arranged in each of the first sub-touch driving area SLC1 and the second sub-touch driving area SLC2. Each of the first sub-touch driving area SLC1 and the second sub-touch driving area SLC2 can include two or more light emitting devices ED.

Two or more row lines RL arranged in the first sub-touch driving area SLC1 and two or more row lines RL arranged in the second sub-touch driving area SLC2 may not be connected to each other, and can be arranged separately from each other. Two or more column lines CL arranged in the first sub-touch driving area SLC1 and two or more column lines CL arranged in the second sub-touch driving area SLC2 may not be connected to each other, and can be arranged separately from each other.

The two sub-touch driving areas SLC1 and SLC2 can correspond to the two sub-driving areas SDA1 and SDA2 included in one unit driving area UDA in FIG. 4, FIG. 5, and FIG. 8, respectively.

One unit touch driving area UTA can include two touch sub-pixel areas TSP. One unit touch driving area UTA can include two sub-touch driving areas SLC1 and SLC2 included in each of two touch sub-pixel areas TSP. For example, one unit touch driving area UTA can include four sub-touch driving areas. One unit touch driving area UTA can include two drivers DRV.

For example, a touch pixel area TP can include 16 touch sub-pixel areas TSP arranged in four rows and four columns. Each of the 16 touch sub-pixel areas TSP can include one driver DRV and two sub-touch driving areas SLC1 and SLC2.

As an example, during a touch driving period for touch sensing, all four sub-touch driving areas included in one unit touch driving area UTA can be driven and sensed. Accordingly, during a touch driving period for touch sensing, each of the two drivers DRV included in one unit touch driving area UTA can drive and sense all two sub-touch driving areas SLC1 and SLC2 included in the corresponding touch sub-pixel area TSP.

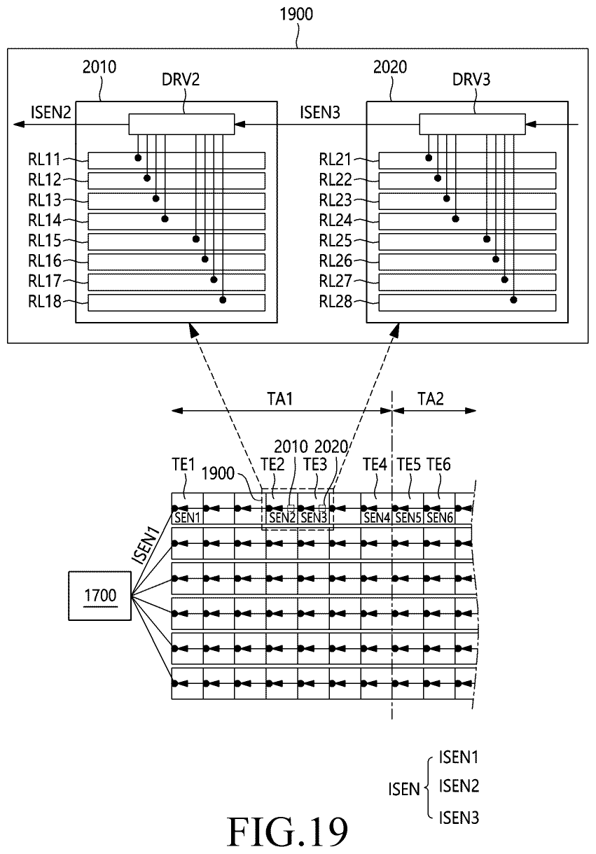

As another example, during a touch driving period for touch sensing, only some of the four sub-touch driving areas included in one unit touch driving area UTA can be driven and sensed. According to the example of FIG. 19, during the touch driving period for touch sensing, only one sub-touch driving area among four sub-touch driving areas included in one unit touch driving area UTA can be driven and sensed. Accordingly, during the touch driving period for touch sensing, only one driver DRV among two drivers DRV included in one unit touch driving area UTA can drive and sense one of two sub-touch driving areas SLC1 and SLC2 included in the corresponding touch sub-pixel area TSP.

According to the embodiments of the present disclosure, the fact that the sub-touch driving area is driven and sensed can mean that two or more row lines RL arranged in the sub-touch driving area are driven (i.e., touch driven) and sensed.

The fact that two or more row lines RL arranged in the sub-touch driving area are driven (i.e., touch driven) can mean that a touch driving signal TDS having a variable voltage level is applied to two or more row lines RL arranged in the sub-touch driving area.

Referring to FIG. 14, in the touch pixel area TP, the sub-touch driving area where touch driving and touch sensing are performed can be arranged in a zigzag shape.

For example, if a touch pixel area TP includes 16 touch sub-pixel areas TSP arranged in four rows and four columns, in each of the first touch sub-pixel row Row #1 and the third touch sub-pixel row Row #3, the second sub-touch driving area SLC2 among the two sub-touch driving areas SLC1 and SLC2 included in the touch sub-pixel area TSP located in the first column Col #1 can be driven and sensed, the two sub-touch driving areas SLC1 and SLC2 included in the touch sub-pixel area TSP located in the second column Col #2 can be not driven and sensed. In addition, the second sub-touch driving area SLC2 among the two sub-touch driving areas SLC1 and SLC2 included in the touch sub-pixel area TSP located in the third column Col #3 can be driven and sensed, and the two sub-touch driving areas SLC1 and SLC2 included in the touch sub-pixel area TSP located in the fourth column Col #4 may not be driven and sensed.

In the second touch sub-pixel row Row #2 and the fourth touch sub-pixel row Row #4, the two sub-touch driving areas SLC1 and SLC2 included in the touch sub-pixel area TSP located in the first column Col #1 may not be driven and sensed, and the second sub-touch driving area SLC2 among the two sub-touch driving areas SLC1 and SLC2 included in the touch sub-pixel area TSP located in the second column Col #2 can be driven and sensed. In addition, the two sub-touch driving areas SLC1 and SLC2 included in the touch sub-pixel area TSP located in the third column Col #3 may not be driven and sensed, and the second sub-touch driving area SLC2 among the two sub-touch driving areas SLC1 and SLC2 included in the touch sub-pixel area TSP located in the fourth column Col #4 can be driven and sensed.

One touch pixel area TP includes a plurality of touch sub-pixel areas TSP, and each of the plurality of touch sub-pixel areas TSP can include two or more row lines RL and two or more column lines CL. Each of the plurality of touch sub-pixel areas TSP can include two or more light emitting devices ED.

One touch pixel area TP includes a plurality of touch sub-pixel areas TSP, and each of the plurality of touch sub-pixel areas TSP can include two sub-touch driving areas SLC1 and SLC2. Each of the two sub-touch driving areas SLC1 and SLC2 can include two or more row lines RL and two or more column lines CL. Each of the two sub-touch driving areas SLC1 and SLC2 can include two or more light emitting devices ED.

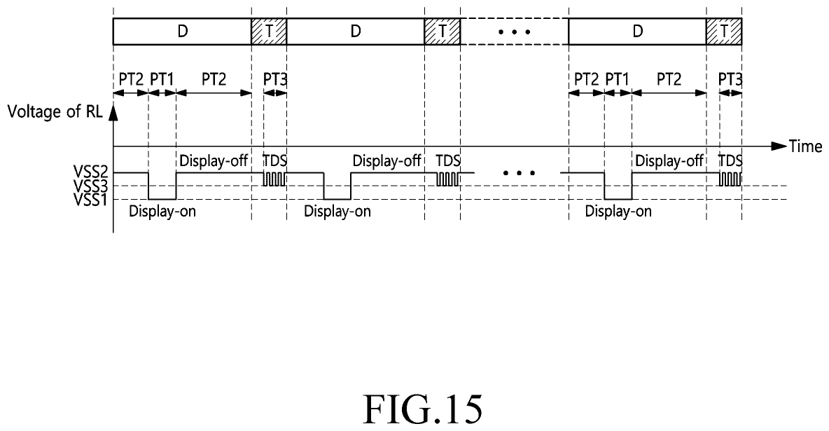

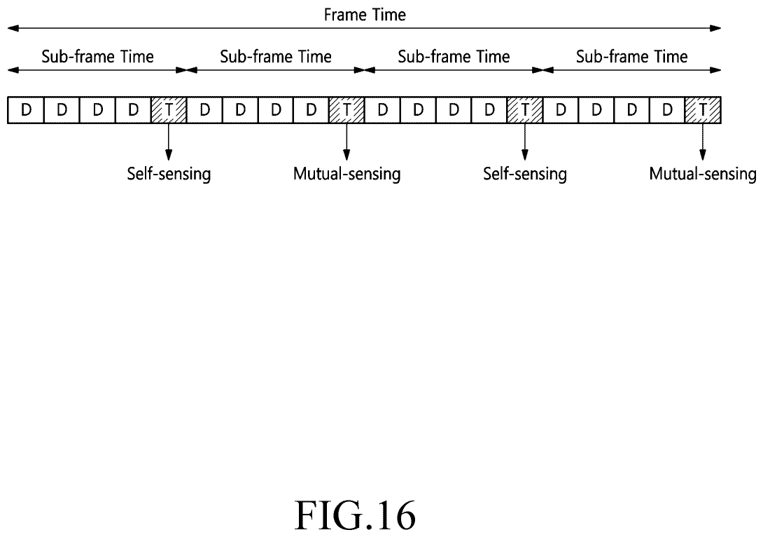

FIG. 15 and FIG. 16 are driving timing diagrams of a display device 100 according to embodiments of the present disclosure.

Referring to FIG. 15 and FIG. 16, the display device 100 according to the embodiments of the present disclosure can perform display driving for image display and touch driving (or touch sensing) for touch sensing. The display device 100 according to the embodiments of the present disclosure can allocate a display driving period D and a touch driving period T, perform display driving during the display driving period D, and perform touch driving during the touch driving period T.

The display device 100 according to the embodiments of the present disclosure can perform display driving and touch driving according to a time-division driving method or a simultaneous driving method.

For example, the display device 100 according to the embodiments of the present disclosure can allocate the display driving period D and the touch driving period T as separate time periods according to the time-division driving method, and can perform display driving during the display driving period D and perform touch driving during the touch driving period T different from the display driving period D.

As another example, the display device 100 according to the embodiments of the present disclosure can perform display driving and touch driving simultaneously during the display driving period D and the touch driving period T that overlap in time according to the simultaneous driving method.

Hereinafter, for the convenience of explanation, the display device 100 according to the embodiments of the present disclosure performs display driving and touch driving at different time periods according to the time division driving method as an example. However, this is not limited thereto.

As an example of a time division driving method, as illustrated in FIG. 15, one display driving period D and one touch driving period T can alternately proceed. For example, one display driving period D can proceed, and then one touch driving period T can proceed.

As an example, one display driving period D can be a period during which display driving is performed to display an image on the entire screen. For example, the period that is the sum of one display driving period D and one touch driving period T can be a frame time. In this case, one display driving period D can correspond to an active period among the active time and a blank time included in one frame time, and one touch driving period T can correspond to a blank time among the active time and blank time included in one frame time.

As another example, two or more display driving periods D can be a period during which display driving is performed to display an image on the entire screen. For example, the time period that is the sum of two or more display driving periods D and two or more touch driving periods T can be a frame time. In this case, one frame time can include two or more sub-frame times. Each of the two or more sub-frame times can include a sub-active time and a sub-blank time. The time summing one display driving period D and one touch driving period T can be one sub-frame time among two or more sub-frame times included in one frame time. One display driving period D included in one sub-frame time can correspond to a sub-active time, and one touch driving period T can correspond to a sub-blank time.

As another example of the time division driving method, as illustrated in FIG. 16, a plurality of display driving periods D and one touch driving period T can alternately proceed. For example, a plurality of display driving periods D can proceed, and then one touch driving period T can proceed.

According to the example of FIG. 16, four display driving periods D can be performed, and then one touch driving period T can be performed. For example, the time summing four display driving periods D and one touch driving period T can correspond to one sub-frame time, and the time summing four sub-frame times can correspond to one frame time for displaying an image on the entire screen.

According to the example of FIG. 16, four touch driving periods T included in one frame time can include self-sensing-based touch driving periods T and mutual-sensing-based touch driving periods T that are alternately proceeded. For example, among the four touch driving periods T included in one frame time, the first and third touch driving periods T can be self-sensing-based touch driving periods T, and the second and fourth touch driving periods T can be mutual-sensing-based touch driving periods T.

Referring to FIG. 15, a plurality of row lines RL can simultaneously perform the role of a cathode electrode (or an anode electrode) for display driving and the role of a touch sensor (e.g., touch electrode) for touch driving. Therefore, the electrical state of the row line RL during the display driving period D and the electrical state of the row line RL during the touch driving period T can be different.

One row line RL among the plurality of row lines RL can be supplied with a first low-potential voltage VSS1 during a first period PT1, and can be supplied with a second low-potential voltage VSS2 during a second period PT2 different from the first period PT1.

The first period PT1 and the second period PT2 can be periods included in one display driving period D or periods included in different display driving periods D.

The first low-potential voltage VSS1 and the second low-potential voltage VSS2 are a type of low-potential voltage VSS and can be a row line voltage applied to the row line RL. In addition, the first low-potential voltage VSS1 and the second low-potential voltage VSS2 can be a voltage (for example, a cathode voltage or an anode voltage) applied to the second electrode Erl of the light emitting devices ED connected to the row line RL.

Among the first low-potential voltage VSS1 and the second low-potential voltage VSS2, the first low-potential voltage VSS1 can be a low-potential voltage for driving the display-on, and the second low-potential voltage VSS2 can be a low-potential voltage for driving the display-off.

The first low-potential voltage VSS1 can be a voltage lower than the second low-potential voltage VSS2. For example, the second low-potential voltage VSS2 can be a higher voltage than the first low-potential voltage VSS1. Accordingly, during the first period PT1, the voltage difference between the first electrode Ecl and the second electrode Erl of the light emitting device ED can be higher than the threshold voltage of the light emitting device ED. Accordingly, the light emitting device ED can be in a state capable of emitting light. Then, during the second period PT2, the voltage difference between the first electrode Ecl and the second electrode Erl of the light emitting device ED can be lower than the threshold voltage of the light emitting device ED. Accordingly, the light emitting device ED can be in a state in which it cannot emit light.

Meanwhile, one of the plurality of row lines RL can be supplied with a touch driving signal TDS, which is a signal whose voltage level swings, during a third period PT3 different from the first period PT1 and the second period PT2.

The third period PT3 can be a period included in the touch driving period T. The touch driving signal TDS can be a signal having a predetermined frequency and whose voltage level fluctuates. The touch driving signal TDS can be a signal that swings between a predefined high voltage and a low voltage. For example, the high voltage can be a second low-potential voltage VSS2, and the low voltage can be a third low-potential voltage VSS3. The amplitude of the touch driving signal TDS can be a voltage difference between the high voltage and the low voltage. For example, the third low-potential voltage VSS3 can be a voltage lower than the second low-potential voltage VSS2 and can be the same as or different from the first low-potential voltage VSS1. For example, the third low-potential voltage VSS3 can be a voltage higher than the first low-potential voltage VSS1 and lower than the second low-potential voltage VSS2.

Depending on the driving type and driving timing, each of the plurality of row lines RL can be driven in a predetermined method.

For example, the display-on driving for each of the plurality of row lines RL can be performed sequentially. For another example, the display-on driving for each of the plurality of row lines RL can be performed simultaneously. For another example, the display-on driving for each of two or more row lines RL among the plurality of row lines RL can be performed simultaneously.

For example, during a specific display driving period, among the plurality of row lines RL arranged in the unit driving area UDA, display-on driving can be performed for at least one row line RL, and display-off driving can be performed for the remaining row lines RL without display-on driving.

The display-on driving performed for a specific row line RL can mean that a first low-potential voltage VSS1 of a predefined level is supplied to the corresponding row line RL.

When the display-on driving for a specific row line RL is performed, the light emitting devices ED arranged corresponding to the corresponding row line RL can emit light.

The display-off driving performed for a specific row line RL without display-on driving can mean that a second low-potential voltage VSS2 of a predefined level is supplied to the corresponding row line RL. Here, the second low-potential voltage VSS2 can be a higher voltage than the first low-potential voltage VSS1.

When display-off driving is performed for a specific row line RL, the light emitting devices ED arranged corresponding to the row line RL may not emit light.

For example, a first row line RL among the plurality of row lines RL can be supplied with a first low-potential voltage VSS1 during a first period, and can be supplied with a second low-potential voltage VSS2 higher than the first low-potential voltage VSS1 during a second period different from the first period. For example, the first period and the second period can be included in one display driving period. For another example, the first period and the second period can be included in different display driving periods.

Referring to FIG. 1, the display device 100 can be a flat shape that does not be folded or bent. The display device 100 can be a fixed shape that does not change shape. However, the display device 100 can include a plurality of display areas, and a space between the plurality of display areas can be bent. For example, the display device 100 can be a foldable display device 100. If the display device 100 is in a folded state, the number of display areas can be 1, and if the display device 100 is in an unfolded state, the number of display areas can be 2 or more. Hereinafter, a foldable display device 100 will be described.

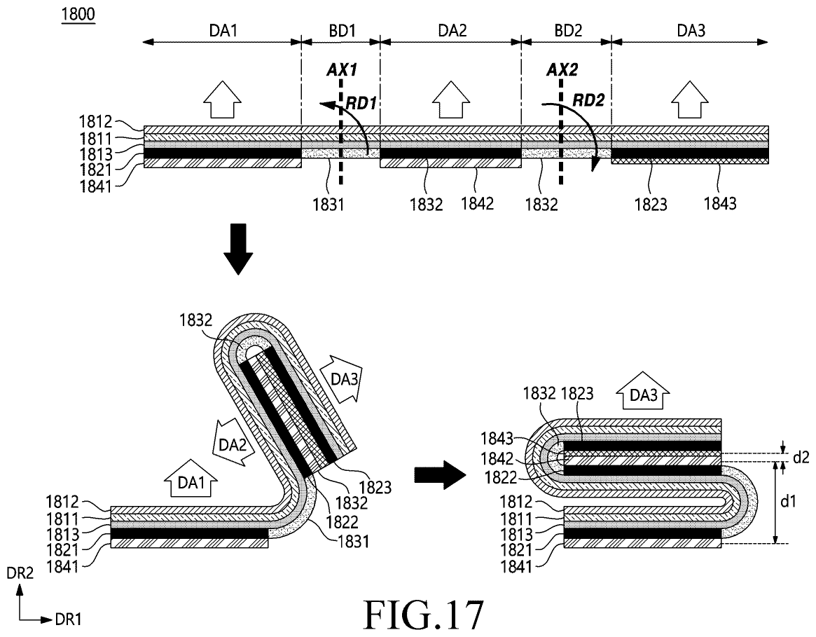

FIG. 17 is a cross-sectional view of a foldable display device 100 according to embodiments of the present disclosure.

Referring to FIG. 17 illustrates a display device 100 being folded or unfolded.

The features of the display device 100 illustrated in FIG. 17 can be the same as the features of the display device 100 illustrated in FIGS. 1 to 16. For example, the light emitting device ED, the column line CL, the row line RL, the display operation, the touch operation included in the display device 100 can be the same as the features of the display device 100 illustrated in FIGS. 1 to 16.

The display device 100 can have an in-cell touch structure in which touch sensing is performed through the row line RL. However, for convenience of explanation, FIG. 17 illustrates a case in which the display device 100 includes a display unit 1811 and a touch panel unit 1812, and the touch panel unit 1812 is disposed on the display unit 1811.

The display unit 1811 can include a substrate 210, a light emitting device ED, a column line CL, a row line RL, a driver DRV, and the display unit 1811 can emit light to display an image.

The display unit 1811 can be a display panel 110 formed integrally. The display unit 1811 can include a first display area DA1, a first bending area BD1, a second display area DA2, a second bending area BD2, and a third display area DA3.

The first bending area BD1 can be positioned adjacent to the first display area DA1 in a first direction DR1. The first bending area BD1 can be a region capable of folding or bending.

The second display area DA2 can be positioned adjacent to the first bending area BD1 in the first direction DR1.

The second bending area BD2 can be positioned adjacent to the second display area DA2 in a first direction DR1. The second bending area BD2 can be a foldable or bendable area.

The third display area DA3 can be positioned adjacent to the second bending area BD2 in the first direction DR1.

The touch panel unit 1812 can be disposed on the display unit 1811, and the touch panel unit 1812 can include a plurality of touch electrodes TE. The plurality of touch electrodes TE can be configured by a plurality of row lines RL.

A first adhesive layer 1813 can be disposed under the display unit 1811. The first adhesive layer 1813 can include a material having adhesive properties. For example, the first adhesive layer 1813 can be OCA, PSA, etc.

A first bottom plate 1821 can be disposed under the first adhesive layer 1813. The first bottom plate 1821 can include a hard material that does not bend easily. The first bottom plate 1821 can be located in the first display area DA1. Since the first bottom plate 1821 is located under the display unit 1811 in the first display area DA1, the display unit 1811 corresponding to the first display area DA1 may not bend and can be maintained to be flat.

A second bottom plate 1822 can be disposed under the first adhesive layer 1813. The second bottom plate 1822 can include a hard material that does not bend easily. The second bottom plate 1822 can be located in the second display area DA2. Since the second bottom plate 1822 is disposed under the display unit 1811 in the second display area DA2, the display unit 1811 corresponding to the second display area DA2 may not be bent and can be maintained to be flat.

A third bottom plate 1823 can be disposed under the first adhesive layer 1813. The third bottom plate 1823 can include a hard material that does not easily bend. The third bottom plate 1823 can be located in the third display area DA3. Since the third bottom plate 1823 is disposed under the display unit 1811 in the third display area DA3, the display unit 1811 corresponding to the third display area DA3 may not be bent and can be maintained to be flat.

A first hinge portion 1831 can connect the first bottom plate 1821 and the second bottom plate 1822. The first hinge portion 1831 can be bent by an external force. The first hinge portion 1831 can be bent in a first rotation direction RD1. Referring to FIG. 17, the first rotation direction RD1 can be counterclockwise.

A second hinge portion 1832 can connect the first bottom plate 1821 and the second bottom plate 1822. The second hinge portion 1832 can be bent by an external force. The second hinge portion 1832 can be bent in a second rotation direction RD2. Referring to FIG. 17, the second rotation direction RD2 can be clockwise. The second rotation direction RD2 can be the opposite direction to the first rotation direction RD1.

A first frame 1841 can be disposed under the first bottom plate 1821. For convenience of explanation, the first frame 1841 is illustrated as being placed under the first bottom plate 1821, but the first frame 1841 can surround the outer periphery of each of the touch panel unit 1812, the display unit 1811, the first adhesive layer 1813, and the first bottom plate 1821, and can protect the corresponding components from the outside.

A second frame 1842 can be disposed under the second bottom plate 1822. For convenience of explanation, the second frame 1842 is illustrated as being placed below the second bottom plate 1822, but the second frame 1842 can surround the periphery of each of the touch panel unit 1812, the display unit 1811, the first adhesive layer 1813, and the second bottom plate 1822, and can protect the components from the outside.

A second adhesive layer 1843 can be disposed under the second bottom plate 1822. For convenience of explanation, the second adhesive layer 1843 is illustrated as being arranged at the bottom of the second bottom plate 1822. However, the second adhesive layer 1843 can surround the outer periphery of each of the touch panel unit 1812, the display unit 1811, the first adhesive layer 1813, and the second bottom plate 1822, and can protect the components from the outside.

The first hinge portion 1831 can be bent in the first rotation direction RD1 with respect to a first axis AX1. The second hinge portion 1832 can be bent in the second rotation direction RD2 with respect to a second axis AX2.

The display device 100 is illustrated to be folded.

When the display device 100 is completely folded, the display areas DA1, DA2 and DA3 of the display device 100 can overlap with each other.

When the display device 100 is in an unfolded state, an image can be displayed through the first display area DA1, the first bending area BD1, the second display area DA2, the second bending area BD2, and the third display area DA3 of the display unit 1811. When the display device 100 is in an unfolded state, the first hinge portion 1831 and the second hinge portion 1832 can be in an unfolded state.

When the display device 100 is in a folded state, an image can be displayed only through the third display area DA3 of the display device 100. When the display device 100 is in a folded state, the first hinge portion 1831 and the second hinge portion 1832 can be in a folded state.

After the first hinge portion 1831 and the second hinge portion 1832 are bent, a first distance d1 from the second frame 1842 to the first frame 1841 can be greater than a second distance d2 from the second frame 1842 to the second adhesive layer 1843.

After the first hinge portion 1831 and the second hinge portion 1832 are bent, the second frame 1842 can be in contact with the second adhesive layer 1843.

After the first hinge portion 1831 and the second hinge portion 1832 are bent, the light emitting devices ED arranged in the first display area DA1 and the second display area DA2 may not emit light, and an image can be displayed through the light emitting devices ED arranged in the third display area DA3.

After the first hinge portion 1831 and the second hinge portion 1832 are bent, the third display area DA3 can overlap the first display area DA1 and the second display area DA2.

After the first hinge portion 1831 and the second hinge portion 1832 are bent, a screen indicating time information can be displayed in the third display area DA3. For example, the display device 100 can perform a function similar to a watch or a clock.

After the first hinge portion 1831 and the second hinge portion 1832 are bent, the driver DRV can detect a touch operation occurring in the third display area DA3 during a touch sensing period.

After the first hinge portion 1831 and the second hinge portion 1832 are bent, during the touch sensing period, the driver DRV can supply a touch driving signal to a row line RL located in the third display area DA3 among the plurality of row lines RL.

For example, the display device 100 can be folded or unfolded. When the display device 100 is unfolded, an image is displayed through the display areas DA1, DA2 and DA3 and the bending areas BD1 and BD2, and a touch operation can also be possible. When the display device 100 is folded, an image is displayed through the third display area DA3, and a touch operation can be possible. Hereinafter, the touch operation of the display device 100 will be described.

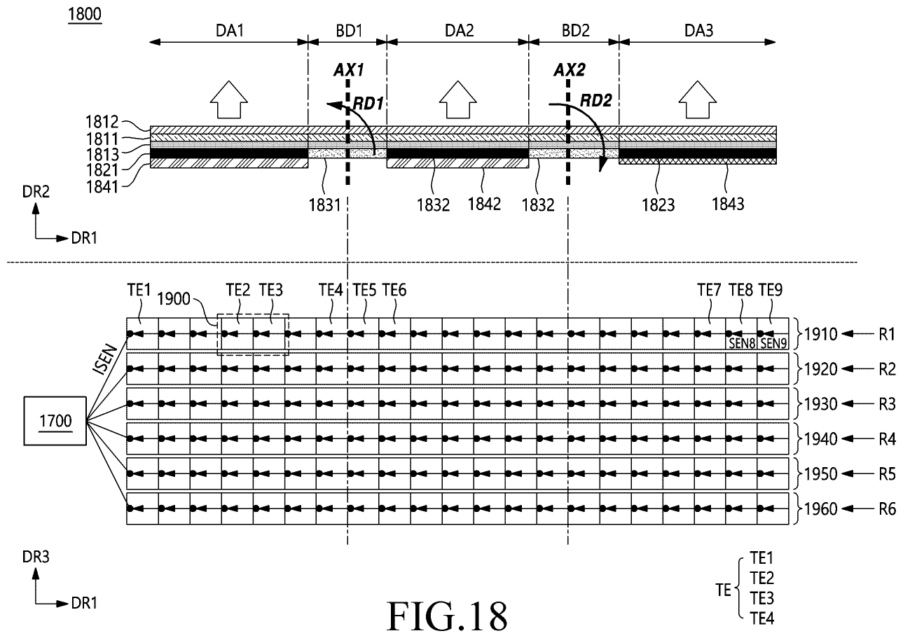

FIG. 18 illustrates touch electrodes TE located in a touch area according to embodiments of the present disclosure.

Referring to FIG. 18, the display device 100 can include a first touch area TA1, a second touch area TA2, and a third touch area TA3. The touch areas can be areas where a plurality of touch electrodes TE are arranged.

The first touch area TA1 can overlap with the first display area DA1. The first touch area TA1 can overlap with a part of the first bending area BD1. The location of the boundary between the first touch area TA1 and the second touch area TA2 can correspond to the first axis AX1.

The second touch area TA2 can overlap with the second display area DA2. The second touch area TA2 can overlap with a part of the first bending area BD1 and a part of the second bending area BD2. The location of the boundary between the second touch area TA2 and the third touch area TA3 can correspond to the second axis AX2. The second touch area TA2 can be positioned apart from the first touch area TA1 in the first direction DR1.

The third touch area TA3 can overlap with the third display area DA3. The third touch area TA3 can overlap with a part of the second bending area BD2. The third touch area TA3 can be positioned apart from the second touch area TA2 in the first direction DR1.

The first touch area TA1 can include a plurality of touch electrodes TE. For example, a plurality of touch electrodes TE can be arranged in a matrix shape of 7*6, and the number of the plurality of touch electrodes TE can be 42. However, the shape and number of the plurality of touch electrodes TE are not limited thereto.

Each of the second touch area TA2 and the third touch area TA3 can include a plurality of touch electrodes TE. For example, in each of the second touch area TA2 and the third touch area TA3, the plurality of touch electrodes TE can be arranged in a matrix form of 7*6, and the number of the plurality of touch electrodes TE can be 42.

The plurality of touch electrodes TE can be used for self-sensing-based touch driving or mutual-sensing-based touch driving. Hereinafter, a self-sensing-based touch driving method will be described.

A first row touch electrode group 1910 can be located in a first row R1. The first row touch electrode group 1910 can include touch electrodes TE located in the first row R1 of each of the first touch area TA1, the second touch area TA2, and the third touch area TA3.

For example, the first row touch electrode group 1910 can include a first touch electrode TE1 to a fourth touch electrode TE4 of the first touch area TA1, a fifth touch electrode TE5 to a sixth touch electrode TE6 of the second touch area TA2, and a seventh touch electrode TE7 to a ninth touch electrode TE9 of the third touch area TA3.

A second row touch electrode group 1920 can be located in a second row R2. The second row touch electrode group 1920 can include touch electrodes TE located in the second row R2 of each of the first touch area TA1, the second touch area TA2, and the third touch area TA3.

A third row touch electrode group 1930 can be located in a third row R3. The third row touch electrode group 1930 can include touch electrodes TE located in the third row R3 of each of the first touch area TA1, the second touch area TA2, and the third touch area TA3.

A fourth row touch electrode group 1940 can be located in a fourth row R4. The fourth row touch electrode group 1940 can include touch electrodes TE positioned in the fourth row R4 of each of the first touch area TA1, the second touch area TA2, and the third touch area TA3.

A fifth row touch electrode group 1950 can be located in a fifth row R5. The fifth row touch electrode group 1950 can include touch electrodes TE positioned in the fifth row R5 of each of the first touch area TA1, the second touch area TA2, and the third touch area TA3.

A sixth row touch electrode group 1960 can be located in a sixth row R6. The sixth row touch electrode group 1960 can include touch electrodes TE located in the sixth row R6 of each of the first touch area TA1, the second touch area TA2, and the third touch area TA3.

Each of the first row touch electrode group 1910 to the sixth row touch electrode group 1960 can be electrically connected to a touch control circuit 1700. Each of the first row touch electrode group 1910 to the sixth row touch electrode group 1960 can transmit integrated sensing data ISEN to the touch control circuit 1700.

Referring to FIG. 18, for example, the first row touch electrode group 1910 can include the first touch electrode TE1 to the ninth touch electrode TE9. The ninth sensing data SEN9 for the ninth touch electrode TE9 can be transmitted to a driver DRV that drives the eighth touch electrode TE8. In this case, the integrated sensing data ISEN can be generated by additionally storing the eighth sensing data SEN8 for the eighth touch electrode TE8 to the ninth sensing data SEN9. The ninth sensing data SEN9 can be shifted, and the eighth sensing data SEN8 can be stored in the bit position where the ninth sensing data SEN9 is shifted. The integrated sensing data ISEN will be described in more detail below.

FIG. 19 illustrates a process of transmitting integrated sensing data ISEN according to embodiments of the present disclosure

The process of generating integrated sensing data ISEN is as follows. Integrated sensing data ISEN can be generated for each of the first row touch electrode group 1910 to the sixth row touch electrode group 1960, and for example, there can be six integrated sensing data ISEN. Hereinafter, it will be described the integrated sensing data ISEN of the first row touch electrode group 1910 for the first row R1 as an example.

Based on the plan views of FIG. 18 and FIG. 19, integrated sensing data ISEN can be accumulated starting from sensing data SEN9 for the rightmost touch electrode TE9. After the sensing data SEN9 of the rightmost touch electrode TE9 is accumulated in the integrated sensing data ISEN, the sensing data SEN8 of the touch electrode TE8 arranged on the left thereof can be additionally accumulated in the integrated sensing data ISEN.

Referring to FIG. 19, for example, the integrated sensing data ISEN can include the first sensing data to the sixth sensing data SEN1, SEN2, SEN3, SEN4, SEN5 and SEN6. Before the integrated sensing data ISEN includes the fifth sensing data SEN5, the integrated sensing data ISEN can include the sensing data SEN for each of the touch electrodes TE located between the sixth touch electrode TE6 and the ninth touch electrode TE9. Thereafter, the integrated sensing data ISEN can include the fifth sensing data SEN5. When the integrated sensing data ISEN additionally stores data, data shift can be performed. The existing data in which the integrated sensing data ISEN is stored can have their positions shifted, and then new sensing data can be stored therein.

A second touch electrode TE2 and a third touch electrode TE3 can be positioned in a first enlarged area 1900.

A plurality of drivers DRV can be disposed in the area where the second touch electrode TE2 is arranged. The plurality of drivers DRV can include a second driver DRV2 positioned in a second enlarged area 2010. The second driver DRV2 can supply a touch driving signal to a plurality of row lines RL11, . . . RL18. The second driver DRV2 can receive a touch sensing signal through a plurality of row lines RL11, . . . RL18.

A plurality of drivers DRV can be disposed in an area where a third touch electrode TE3 is arranged. The plurality of drivers DRV can include a third driver DRV3 located in a third enlarged area 2020. The third driver DRV3 can supply a touch driving signal to a plurality of row lines RL21, . . . , RL28. The third driver DRV3 can receive a touch sensing signal through the plurality of row lines RL21, . . . , RL28.

The third driver DRV3 can be electrically connected to the second driver DRV2. The third driver DRV3 can transmit integrated sensing data ISEN3 including the third sensing data SEN3 to the second driver DRV2.

The second driver DRV2 can store the second sensing data ISEN2 in the integrated sensing data ISEN3 including the third sensing data SEN3 through data shift, and thereby generate the integrated sensing data ISEN2 including the second sensing data SEN2.

The second driver DRV2 and the third driver DRV3 can be integrated drivers DRV for display driving and touch driving. However, the second driver DRV2 and the third driver DRV3 can be drivers DRV for touch driving, and a driver DRV for display driving can be provided separately.

The integrated sensing data ISEN1 including the first sensing data SEN1 can be generated, and the integrated sensing data ISEN1 can be supplied to the touch control circuit 1700. The touch control circuit 1700 can interpret sensing data for each of the touch electrodes TE included in the first row touch electrode group 1910 based on the integrated sensing data ISEN1. In addition, touch control circuit 1700 can determine the presence or absence of a touch operation and the touch coordinates for each of the touch electrodes TE based on the sensing data.

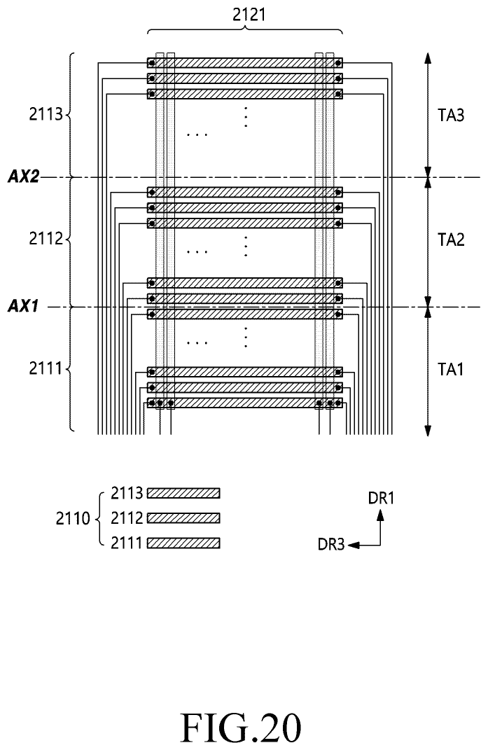

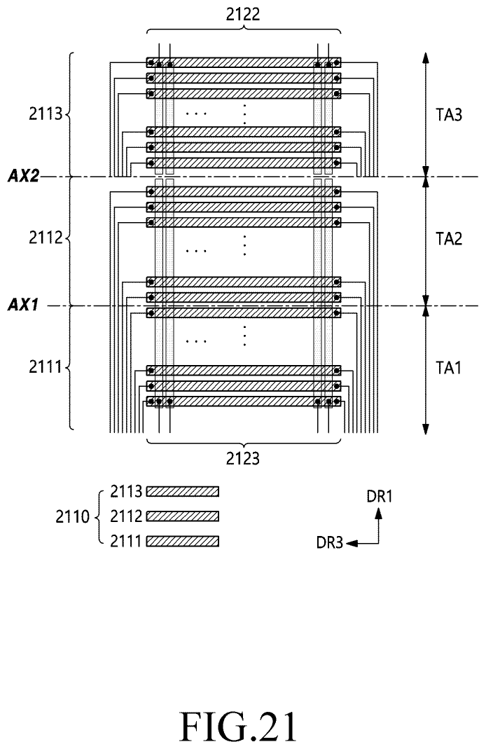

FIG. 20 and FIG. 21 illustrate a touch electrode TE according to embodiments of the present disclosure.

Referring to FIG. 20, the touch electrode TE can include a plurality of transmitting electrodes 2121 and a plurality of receiving electrodes 2110.

The plurality of transmitting electrodes 2121 and the plurality of receiving electrodes 2110 can be formed of a metal.

The plurality of transmitting electrodes 2121 can extend in a first direction DR1. The plurality of transmitting electrodes 2121 can be electrodes that receive a touch driving signal.

The plurality of receiving electrodes 2110 can extend in a third direction DR3. The plurality of receiving electrodes 2110 can transmit a touch sensing signal to a touch control circuit.

The plurality of transmitting electrodes 2121 can be disposed in the first touch area TA1, the second touch area TA2, and the third touch area TA3. For example, the plurality of transmitting electrodes 2121 can extend from the first touch area TA1 to the third touch area TA3.

The plurality of receiving electrodes 2110 can include a first receiving electrode group 2111, a second receiving electrode group 2112, and a third receiving electrode group 2113. The first receiving electrode group 2111 can be disposed in the first touch area TA1. The second receiving electrode group 2112 can be disposed in the second touch area TA2. The third receiving electrode group 2113 can be disposed in the third touch area TA3.

In the case that the display device 100 is in an unfolded state, a touch driving signal can be supplied through a plurality of transmitting electrodes 2121. In addition, a plurality of receiving electrodes 2110 located in the first touch area TA1 to the third touch area TA3 can supply a touch sensing signal to the touch control circuit.

In the case that the display device 100 is in a folded state, a touch driving signal can be supplied through a plurality of transmitting electrodes 2121. In the folded state, since the first touch area TA1 and the second touch area TA2 do not need to be driven, the touch control circuit can receive a touch sensing signal only through the third receiving electrode group 2113 located in the third touch area TA3. In this case, since only the third receiving electrode group 2113 located in the third touch area TA3 is driven, it is possible to reduce the power consumption.

FIG. 21 illustrates a plurality of transmitting electrodes 2122 and 2123 and a plurality of receiving electrodes 2110. The plurality of receiving electrodes 2110 illustrated in FIG. 21 can be identical to the plurality of receiving electrodes 2110 illustrated in FIG. 20.

Referring to FIG. 21, the plurality of transmitting electrodes 2122 and 2123 can include a first transmitting electrode group 2122 and a second transmitting electrode group 2123. The first transmitting electrode group 2122 can be located in the third touch area TA3. The second transmitting electrode group 2123 can be located in the second touch area TA2 and the first touch area TA1.

The first transmitting electrode group 2122 can extend in the first direction DR1 and be located in the third touch area TA3.

The second transmitting electrode group 2123 can extend in the first direction DR1 and can be located in the second touch area TA2 and the first touch area TA1.

The first transmitting electrode group 2122 can be positioned spaced apart from the second transmitting electrode group 2123. The first transmitting electrode group 2122 can be electrically separated from the second transmitting electrode group 2123.

In the case that the display device 100 is in an unfolded state, a touch driving signal can be supplied through a plurality of transmitting electrodes. For example, the first transmitting electrode group 2122 can supply a touch driving signal to the third touch area TA3, and the second transmitting electrode group 2123 can supply a touch driving signal to the second touch area TA2 and the first touch area TA1. In addition, a plurality of touch receiving electrodes located in the first touch area TA1 to the third touch area TA3 can supply a touch sensing signal to the touch control circuit.

In the case that the display device 100 is in a folded state, a touch driving signal can be supplied through a plurality of transmitting electrodes. In the folded state, the first touch area TA1 and the second touch area TA2 do not need to be driven, and the user's touch operation can be detected only by driving the third touch area TA3. Therefore, even if only the first transmitting electrode group 2122 and the third receiving electrode group 2113 located in the third touch area TA3 are driven, the touch driving of the display device 100 in the folded state can be performed. In this case, since only the first transmitting electrode group 2122 and the third receiving electrode group 2113 located in the third touch area are driven, it is possible to reduce the power consumption.

A display device according to embodiments of the present disclosure can be described as follows.

Embodiments of the present disclosure can provide a display device including a substrate including a plurality of display areas, and being able to be bent between the plurality of display areas, a plurality of drivers disposed on the substrate and positioned in the plurality of display areas, a plurality of light emitting devices positioned on the plurality of drivers and overlapping with the plurality of drivers, a plurality of column lines electrically connected to a first electrode of each of the plurality of light emitting devices, and a plurality of row lines electrically connected to a second electrode of each of the plurality of light emitting devices. The substrate can include a first display area, a second display area spaced apart from the first display area, a third display area spaced apart from the second display area, a first bending area between the first display area and the second display area, and a second bending area between the second display area and the third display area.

The display device according to embodiments of the present disclosure can further include a first adhesive layer disposed under the substrate, a first bottom plate disposed under the first adhesive layer and overlapping with the first display area, a second bottom plate disposed under the first adhesive layer and overlapping with the second display area, a third bottom plate disposed under the first adhesive layer and overlapping with the third display area, a first hinge portion connecting the first bottom plate and the second bottom plate and overlapping with the first bending area, a second hinge portion connecting the second bottom plate and the third bottom plate and overlapping with the second bending area, a first frame disposed under the first bottom plate, a second frame disposed under the second bottom plate, and a second adhesive layer disposed under the third bottom plate.

The first hinge portion can be bent in a first rotation direction, and the second hinge portion can be bent in a second rotation direction opposite to the first rotation direction. After the first hinge portion and the second hinge portion are bent, a first distance from the second frame to the first frame can be greater than a second distance from the second frame to the second adhesive layer.

After the first hinge portion and the second hinge portion are bent, the second frame can be in contact with the second adhesive layer.

After the first hinge portion and the second hinge portion are bent, a light emitting device disposed in the first display area and the second display area may not emit light, and an image can be displayed through a light emitting device disposed in the third display area.

After the first hinge portion and the second hinge portion are bent, the third display area can overlap with the first display area and the second display area.

After the first hinge portion and the second hinge portion are bent, the third display area can display time information.

After the first hinge portion and the second hinge portion are bent, a first driver included in the plurality of drivers can detect a touch operation occurring in the third display area during a touch sensing period.

After the first hinge portion and the second hinge portion are bent, the first driver can supply a touch driving signal to a row line located in the third display area among the plurality of row lines during the touch sensing period.

The plurality of row lines can be electrically connected to a first driver for a display driving and a second driver for a touch driving, or are electrically connected to a third driver for a display driving and a touch driving.

The display device according to embodiments of the present disclosure can further include a plurality of touch electrodes disposed on the substrate, and each of the plurality of touch electrodes can be formed by combining a portion of the plurality of row lines.

The display device according to embodiments of the present disclosure can further include a first touch electrode positioned in the first display area, a second touch electrode disposed spaced apart from the first touch electrode in a first direction and positioned in the second display area, and a third touch electrode disposed spaced apart from the second touch electrode in the first direction and positioned in the third display area.

The display device according to embodiments of the present disclosure can further include a first driver group overlapping with the first touch electrode, disposed in the first display area, and including at least one driver, a second driver group overlapping with the second touch electrode, disposed in the second display area, and including at least one driver, and a third driver group overlapping with the third touch electrode, disposed in the third display area, and including at least one driver.

A second driver included in the second driver group can be electrically connected to a first driver included in the first driver group and a third driver included in the third driver group.

First sensing data for the third touch electrode can be transmitted from the third driver to the second driver, and the first sensing data can be transmitted from the second driver to the first driver.

The first sensing data can be data shifted in the second driver and integrated with second sensing data for the second touch electrode.

A part of the plurality of light emitting devices can be located in the first bending area and the second bending area, and the first bending area and the second bending area can be areas capable of displaying an image.

The display device according to embodiments of the present disclosure can further include a layer stack on the plurality of drivers disposed on the substrate, an optical layer disposed between the plurality of light emitting devices on the layer stack, an adhesive layer disposed on the plurality of light emitting devices and the optical layer, and a cover member disposed on the adhesive layer. The plurality of column lines can be arranged between the layer stack and the plurality of light emitting devices, and the plurality of row lines can be arranged on the plurality of light emitting devices and the optical layer.

The layer stack can include a side protection layers disposed on each side of the plurality of drivers, an upper protection layers disposed on the plurality of drivers and the side protection layers, a plurality of insulating layers disposed on the upper protection layers, and a bank disposed on the plurality of insulating layers. Each of the plurality of light emitting devices can be disposed on the bank and positioned in an opening of the optical layer. At least a portion of each of the plurality of column lines can extend onto the bank on the plurality of insulating layers. Each of the plurality of row lines can be arranged on the optical layer and the plurality of light emitting devices. The first electrode of each of the plurality of light emitting devices can be electrically connected to at least a portion of a column line extending onto the bank among the plurality of column lines, and the second electrode of each of the plurality of light emitting devices can be electrically connected to one row line among the plurality of row lines.

The plurality of insulating layers can include a first insulating layer on the upper protection layer and a second insulating layer on the second insulating layer, and the layer stack can further include a plurality of line connection patterns connecting each of a plurality of lines including the plurality of row lines and the plurality of column lines to the plurality of drivers. The plurality of line connection patterns can include a first line connection pattern disposed on the side protection layer, a second line connection pattern disposed on the upper protection layer and electrically connected to the first line connection pattern through a hole in the upper protection layer, a third line connection pattern disposed on the first insulating layer and electrically connected to the second line connection pattern through a hole in the first insulating layer, and a fourth line connection pattern disposed on the second insulating layer and electrically connected to the third line connection pattern through a hole in the second insulating layer. The first line connection pattern can be electrically connected to one of the plurality of drivers. The fourth line connection pattern can be electrically connected to the second electrode of at least one of the plurality of light emitting devices, or can be electrically connected to the first electrode of at least one of the plurality of light emitting devices.

A touch driving signal can be supplied to at least some of the plurality of row lines during a touch sensing period.

Embodiments of the present disclosure can provide a display device a substrate including a plurality of display areas, and being able to be bent between the plurality of display areas, a plurality of light emitting devices disposed on a plurality of drivers positioned on the substrate, a plurality of column lines electrically connected to a first electrode of each of the plurality of light emitting devices, and a plurality of row lines electrically connected to a second electrode of each of the plurality of light emitting devices. A touch driving signal can be supplied to at least some of the plurality of row lines during a touch sensing period. The substrate can include a first display area, a second display area spaced apart from the first display area, a third display area spaced apart from the second display area, a first bending area between the first display area and the second display area, and a second bending area between the second display area and the third display area.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the technical idea and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display device comprising:
a substrate including a plurality of display areas, and the substrate configured to be bent between the plurality of display areas;
a plurality of drivers disposed on the substrate, and the plurality of drivers positioned in the plurality of display areas;
a plurality of light emitting devices disposed on the plurality of drivers, and the plurality of light emitting devices overlapping with the plurality of drivers;
a plurality of column lines each electrically connected to a first electrode of one of the plurality of light emitting devices; and
a plurality of row lines each electrically connected to a second electrode of the one of the plurality of light emitting devices,
wherein the substrate includes:
a first display area among the plurality of display areas;
a second display area among the plurality of display areas and spaced apart from the first display area;
a third display area among the plurality of display areas and spaced apart from the second display area;
a first bending area between the first display area and the second display area; and
a second bending area between the second display area and the third display area.

2. The display device of claim 1, further comprising:
a first adhesive layer disposed under the substrate;
a first bottom plate disposed under the first adhesive layer, and the first bottom plate overlapping with the first display area;
a second bottom plate disposed under the first adhesive layer, and the second bottom plate overlapping with the second display area;
a third bottom plate disposed under the first adhesive layer, and the third bottom plate overlapping with the third display area;
a first hinge portion connecting the first bottom plate and the second bottom plate, and the first hinge portion overlapping with the first bending area;
a second hinge portion connecting the second bottom plate and the third bottom plate, and the second hinge portion overlapping with the second bending area;
a first frame disposed under the first bottom plate;
a second frame disposed under the second bottom plate; and
a second adhesive layer disposed under the third bottom plate.

3. The display device of claim 2, wherein the first hinge portion is bent in a first rotation direction,
wherein the second hinge portion is bent in a second rotation direction opposite to the first rotation direction, and
wherein, after the first hinge portion and the second hinge portion are bent, a first distance from the second frame to the first frame is greater than a second distance from the second frame to the second adhesive layer.

4. The display device of claim 3, wherein, after the first hinge portion and the second hinge portion are bent, the second frame is in contact with the second adhesive layer.

5. The display device of claim 3, wherein, after the first hinge portion and the second hinge portion are bent, a light emitting device disposed in the first display area and the second display area, among the plurality of light emitting devices, does not emit light, and
wherein an image is displayed through a light emitting device disposed in the third display area among the plurality of light emitting devices.

6. The display device of claim 3, wherein, after the first hinge portion and the second hinge portion are bent, the third display area overlaps with the first display area and the second display area.

7. The display device of claim 3, wherein, after the first hinge portion and the second hinge portion are bent, the third display area displays time information.

8. The display device of claim 3, wherein, after the first hinge portion and the second hinge portion are bent, a first driver among the plurality of drivers detects a touch operation occurring in the third display area during a touch sensing period.

9. The display device of claim 8, wherein, after the first hinge portion and the second hinge portion are bent, the first driver supplies a touch driving signal to a row line located in the third display area among the plurality of row lines during the touch sensing period.

10. The display device of claim 1, wherein the plurality of drivers include a first driver, a second driver and a third driver, and
wherein the plurality of row lines are electrically connected to the first driver for a display driving and the second driver for a touch driving, or the plurality of row lines are electrically connected to the third driver for a display driving and a touch driving.

11. The display device of claim 1, further comprising a plurality of touch electrodes disposed on the substrate,
wherein each of the plurality of touch electrodes is formed by combining a portion of the plurality of row lines.

12. The display device of claim 11, further comprising:
a first touch electrode disposed in the first display area;
a second touch electrode disposed spaced apart from the first touch electrode in a first direction, and the second touch electrode disposed in the second display area; and
a third touch electrode disposed spaced apart from the second touch electrode in the first direction, and the third touch electrode disposed in the third display area.

13. The display device of claim 12, further comprising:
a first driver group overlapping with the first touch electrode, the first driver group disposed in the first display area, and the first driver group including at least one driver;
a second driver group overlapping with the second touch electrode, the second driver group disposed in the second display area, and the second driver group including at least one driver; and
a third driver group overlapping with the third touch electrode, the third driver group disposed in the third display area, and the third driver group including at least one driver.

14. The display device of claim 13, wherein a second driver included in the second driver group is electrically connected to a first driver included in the first driver group and a third driver included in the third driver group.

15. The display device of claim 14, wherein first sensing data for the third touch electrode is transmitted from the third driver to the second driver, and
wherein the first sensing data is transmitted from the second driver to the first driver.

16. The display device of claim 15, wherein the first sensing data is data shifted in the second driver and integrated with second sensing data for the second touch electrode.

17. The display device of claim 1, wherein a part of the plurality of light emitting devices is located in the first bending area and the second bending area, and
wherein the first bending area and the second bending area are areas capable of displaying an image.

18. The display device of claim 1, further comprising:
a layer stack on the plurality of drivers disposed on the substrate;
an optical layer disposed between the plurality of light emitting devices on the layer stack;
an adhesive layer disposed on the plurality of light emitting devices and the optical layer; and
a cover member disposed on the adhesive layer,
wherein the plurality of column lines are arranged between the layer stack and the plurality of light emitting devices, and
wherein the plurality of row lines are arranged on the plurality of light emitting devices and the optical layer.

19. The display device of claim 18, wherein the layer stack includes:
a side protection layer disposed on each side of the plurality of drivers;
an upper protection layer disposed on the plurality of drivers and the side protection layer;
a plurality of insulating layers disposed on the upper protection layer; and
a bank disposed on the plurality of insulating layers,
wherein each of the plurality of light emitting devices is disposed on the bank and each of the plurality of light emitting devices is disposed in an opening of the optical layer,
wherein at least a portion of each of the plurality of column lines extends onto the bank on the plurality of insulating layers,
wherein each of the plurality of row lines is arranged on the optical layer and the plurality of light emitting devices,
wherein the first electrode of each of the plurality of light emitting devices is electrically connected to at least a portion of a column line extending onto the bank among the plurality of column lines, and
wherein the second electrode of each of the plurality of light emitting devices is electrically connected to one row line among the plurality of row lines.

20. The display device of claim 19, wherein the plurality of insulating layers include a first insulating layer on the upper protection layer and a second insulating layer on the first insulating layer,
wherein the layer stack further includes a plurality of line connection patterns connecting a plurality of lines to the plurality of drivers, the plurality of lines including the plurality of row lines and the plurality of column lines,
wherein the plurality of line connection patterns include:
a first line connection pattern disposed on the side protection layer;
a second line connection pattern disposed on the upper protection layer, and the second line connection pattern electrically connected to the first line connection pattern through a hole in the upper protection layer;
a third line connection pattern disposed on the first insulating layer, and the third line connection pattern electrically connected to the second line connection pattern through a hole in the first insulating layer; and
a fourth line connection pattern disposed on the second insulating layer, and the fourth line connection pattern electrically connected to the third line connection pattern through a hole in the second insulating layer,
wherein the first line connection pattern is electrically connected to one of the plurality of drivers, and
wherein the fourth line connection pattern is electrically connected to the second electrode of at least one of the plurality of light emitting devices, or the fourth line connection pattern is electrically connected to the first electrode of at least one of the plurality of light emitting devices.

21. The display device of claim 1, wherein a touch driving signal is supplied to at least some of the plurality of row lines during a touch sensing period.

22. A display device comprising:
a substrate including a plurality of display areas, and the substrate configured to be bent between the plurality of display areas;
a plurality of light emitting devices disposed on a plurality of drivers disposed on the substrate;
a plurality of column lines electrically connected to first electrodes of the plurality of light emitting devices; and
a plurality of row lines electrically connected to second electrodes of the plurality of light emitting devices,
wherein a touch driving signal is supplied to at least some of the plurality of row lines during a touch sensing period, and
wherein the substrate includes:
a first display area among the plurality of display areas;
a second display area among the plurality of display areas and spaced apart from the first display area;
a third display area among the plurality of display areas and spaced apart from the second display area;
a first bending area between the first display area and the second display area; and
a second bending area between the second display area and the third display area.
